(19) United States
(12) Patent Application Publication
(10) Pub. No.: US 2025/0123366 A1
(43) Pub. Date: Apr. 17, 2025

(54) LASER OUTPUT ARRAY, RECEPTION OPTICS, AND LIDAR DEVICE USING SAME

(71) Applicant: SOS LAB CO., LTD., Gwangju (KR)

(72) Inventors: Hoon Il JEONG, Gwangju-si (KR); Chan M LIM, Yongin-si (KR); Suwoo NOH, Gwangju (KR); Juheon YOON, Seoul (KR)

(21) Appl. No.: 19/000,167

(22) Filed: Dec. 23, 2024

Related U.S. Application Data
(63) Continuation of application No. PCT/KR2023/008612, filed on Jun. 21, 2023.

(30) Foreign Application Priority Data
Jun. 24, 2022 (KR) 10-2022-0077652
Nov. 30, 2022 (KR) 10-2022-0164007

(51) Int. Cl. G01S 7/481

(52) U.S. Cl. CPC G01S 7/4815

(57) ABSTRACT

A lidar device is proposed. The device may include a transmission module including a laser output array and transmission optics, the laser output array including a first laser emitting sub-array, and the first laser emitting sub-array including a first laser emitting unit and a second laser emitting unit. The device may also include a reception module including a laser detecting array and reception optics. The laser detecting array may include a first detecting unit configured to detect a laser beam emitted from the first laser emitting unit and a second detecting unit configured to detect a laser beam emitted from the second laser emitting unit.

### CROSS REFERENCE TO RELATED APPLICATIONS

This is a continuation application of International Patent Application No. PCT/KR2023/008612 filed Jun. 21, 2023, which claims priority to Korean patent application Nos. KR 10-2022-0077652 filed on Jun. 24, 2022, and KR 10-2022-0164007 filed Nov. 30, 2022, the contents of each of which are incorporated herein by reference in their entireties.

### BACKGROUND

### Technical Field

The present disclosure relates to a laser emitting array that emits a laser and a LIDAR device using the same and, more specifically, to a laser emitting array having improved uniformity of power of the emitted laser and a LIDAR device using the same.

### Description of Related Technology

Recently, Light Detection and Ranging (LiDAR) has been in the spotlight along with the growing interest in autonomous vehicles and unmanned vehicles. LiDAR is a device that acquires distance information of the surroundings using lasers, and is being applied to various fields, such as automobiles, drones, and aircraft, due to its superior precision and resolution and the ability to perceive objects in three dimensions.

Meanwhile, a solid-state LiDAR device is a device that may acquire distance information about a three-dimensional surrounding space without a mechanically moving component, and may use a laser emitting array to implement the solid-state LiDAR device.

### SUMMARY

One aspect is a LIDAR device with increased uniformity by using a laser emitting array and a laser detecting array to reduce difference in an amount of light obtained from each detecting unit included in the laser detecting array.

Aspects of the present disclosure are not limited to those described herein, and other aspects not mentioned may be clearly understood by those skilled in the art from this specification and the attached drawings.

Another aspect is a Light detection and ranging (LiDAR) device, comprising: a transmission module comprising a laser emitting array and a transmission optic, wherein the laser emitting array comprises a first laser emitting sub-array, wherein the first laser emitting sub-array comprises a first laser emitting unit and a second laser emitting unit; and a reception module comprising a laser detecting array and a reception optic, wherein the laser detecting array comprises a first detecting unit configured to detect laser emitted from the first laser emitting unit and a second detecting unit configured to detect laser emitted from the second laser emitting unit; wherein the laser emitting array is designed such that a diameter of the first laser emitting unit is larger than a diameter of the second laser emitting unit, wherein the reception optic is designed so that an illumination for a first area of the laser detecting array is greater than an illumination for a second area of the laser detecting array, wherein the first detecting unit is located on the first area of the laser detecting array, and wherein the second detecting unit is located on the second area of the laser detecting array.

The technical solution of the present disclosure is not limited to the above-described solution, and solutions not mentioned will be apparent to those skilled in the art from this specification and the attached drawings.

According to an embodiment of the present disclosure, it is possible to provide a LIDAR device with increased uniformity by using a laser emitting array and a laser detecting array to reduce difference in an amount of light obtained from each detecting unit included in the laser detecting array.

The effects of the present disclosure are not limited to the effects described above, and effects not mentioned may be clearly understood by those skilled in the art from this specification and the attached drawings.

### BRIEF DESCRIPTION OF THE DRAWINGS

FIG. 1 is a diagram illustrating a LIDAR device according to an embodiment.

FIG. 2 is a diagram illustrating various embodiments of a LIDAR device.

FIG. 3 is a diagram illustrating the operation of a LiDAR device and LiDAR data according to an embodiment.

FIG. 4 is a diagram illustrating LiDAR data according to an embodiment.

FIG. 5 is a diagram illustrating LiDAR data according to an embodiment.

FIG. 6 is a diagram illustrating information included in attribute data according to an embodiment.

FIG. 7 is a diagram illustrating a LIDAR device according to an embodiment.

FIG. 8 is a diagram illustrating a laser emitting array and a laser detecting array included in a LIDAR device according to an embodiment.

FIG. 9 and FIG. 10 are diagrams illustrating a LiDAR device according to an embodiment.

FIG. 11 and FIG. 12 are diagrams illustrating a laser emitting module and a laser detecting module according to an embodiment.

FIG. 13 and FIG. 14 are diagrams illustrating an emitting lens module and a detecting lens module according to an embodiment.

FIG. 15 is a diagram illustrating a laser emitting unit according to an embodiment.

FIG. 16 is a diagram illustrating a laser emitting array according to an embodiment.

FIG. 17 is a circuit diagram illustrating an electrical circuit of a laser emitting array according to an embodiment.

FIG. 18 is a diagram illustrating the powers of lasers emitted from a plurality of laser emitting units included in a laser emitting array according to an embodiment.

FIG. 19 is a diagram illustrating an image of a laser emitting array and a method for obtaining the resistance of an upper conductor included in the laser emitting array, according to an embodiment.

FIG. 20 is a circuit diagram illustrating an exemplary electrical circuit of a laser emitting array according to an embodiment.

FIG. 21 and FIG. 22 are diagrams illustrating a laser emitting array according to an embodiment.

FIG. 23 is a diagram illustrating a laser emitting array according to an embodiment.

FIG. 24 is a diagram illustrating a laser emitting array according to an embodiment.

FIG. 25 is a diagram illustrating a laser emitting array according to an embodiment.

FIG. 26 is a diagram illustrating the size and power of laser emitting units included in a laser emitting array according to an embodiment.

FIG. 27 is a diagram illustrating the illumination of a receiving optic included in a LIDAR device according to an embodiment.

FIG. 28 is a diagram illustrating a LIDAR device according to an embodiment.

### DETAILED DESCRIPTION

Since the embodiments described in this specification are intended to clearly explain the idea of the present disclosure to those skilled in the art in the field to which the present disclosure pertains, the present disclosure is not limited to the embodiments described herein, but the scope of the present disclosure should be construed to include modifications or variations that do not depart from the spirit of the present disclosure.

The terms used herein are general terms that are currently widely used as much as possible in consideration of their functions in the present disclosure. This may vary depending on the intention of those skilled in the art in the technical field to which the present disclosure belongs, precedents, or the emergence of new technologies. However, when a specific term is defined and used with an arbitrary meaning, the meaning of the term will be described separately. Therefore, the terms used in this specification should be interpreted based on the actual meaning of the term and the overall content of this specification, not just the name of the term.

The drawings attached herein are intended to easily explain the present disclosure. Since the shapes shown in the drawings may be exaggerated as necessary to aid understanding of the present disclosure, the present disclosure is not limited by the drawings.

When an element or layer described herein is referred to as being “on” another element or layer, it may include both cases where intervening elements or layers may be present, as well as the element or layer may be directly on another element or layer.

Throughout this specification, like reference numerals may in principle refer to like elements.

The terms “first”, “second,” etc., as used in the description of this specification may be understood as identification symbols to distinguish one component from another component.

The terms “module” and “unit” for elements used in the description of this specification are used or mixed to facilitate preparation of the specification, and may not have distinct meanings or roles in themselves.

When it is determined that the detailed description of the known configuration or function related to the present disclosure in this specification may obscure the gist of the present disclosure, detailed explanations regarding this will be omitted as necessary.

According to an embodiment of the present disclosure, there may be provided a Light detection and ranging (LiDAR) device, comprising: a transmission module comprising a laser emitting array and a transmission optic, wherein the laser emitting array comprises a first laser emitting sub-array, wherein the first laser emitting sub-array comprises a first laser emitting unit and a second laser emitting unit; and a reception module comprising a laser detecting array and a reception optic, wherein the laser detecting array comprises a first detecting unit configured to detect laser emitted from the first laser emitting unit and a second detecting unit configured to detect laser emitted from the second laser emitting unit; wherein the laser emitting array is designed such that a diameter of the first laser emitting unit is larger than a diameter of the second laser emitting unit, wherein the reception optic is designed so that an illumination for a first area of the laser detecting array is greater than an illumination for a second area of the laser detecting array, wherein the first detecting unit is located on the first area of the laser detecting array, and wherein the second detecting unit is located on the second area of the laser detecting array.

Herein, the first laser emitting unit is disposed closer to the center of the laser emitting array than the second laser emitting unit.

Herein, the first detecting unit is disposed closer to the center of the laser detecting array than the second detecting unit.

Herein, a power of a first laser emitted from the first laser emitting unit is smaller than a power of a second laser emitted from the second laser emitting unit.

Herein, diameters of a plurality of laser emitting units included in the first laser emitting sub-array are larger as a positions of the laser emitting units are closer to the center of the laser emitting array.

Herein, a ratio of the illumination for the first region of the laser detecting array to the illumination for the second region of the laser detecting array corresponds to a ratio of the power of the laser emitted from the second laser emitting unit to the power of the laser emitted from the first laser emitting unit.

Herein, when the ratio of the power of the laser emitted from the second laser emitting unit to the power of the laser emitted from the first laser emitting unit is X, the ratio of the illumination for the first region of the laser detecting array to the illumination for the second region of the laser detecting array is X.

Herein, the LiDAR device is designed to satisfy the following relationship equation.

### Relationship Equation

The power of the laser emitted from the first laser emitting unit/the power of the laser emitted from the second laser emitting unit*0.8≤a relative illumination on the second detecting unit of the reception optic/a related illumination on the first detecting unit of the reception optic≤the power of the laser emitted from the first laser emitting unit/the power of the laser emitted from the second laser emitting unit*1.2.

Herein, each of the first detecting unit and the second detecting unit comprises a plurality of detecting elements.

Herein, a number of detecting elements included in each of the first detecting unit and the second detecting unit is nine.

Herein, the laser emitting array is provided as a VCSEL (Vertical Cavity Surface Emitting Laser) array, and the laser detecting array is provided as a SPAD (Single Photon Avalanche Diode) array.

Hereinafter, the LiDAR device according to the present disclosure will be described.

However, the LiDAR device described herein may be understood as a concept including different devices that measure distance using lasers, such as Light Detection and Ranging (LiDAR), Time-of-Flight sensor (TOF sensor), and the like, but is not limited thereto.

A LIDAR device is to detect the distance to a target and the position of the target using a laser. For example, the LiDAR device may emit a laser and, when the emitted laser is reflected from the target, may receive the reflected laser to measure the distance between the target and the LiDAR device and the position of the target. Herein, the distance and position of the target may be expressed through a coordinate system. For example, the distance and position of the target may be expressed in a spherical coordinate system (r, θ, φ). However, they are not limited thereto, and may be expressed in an orthogonal coordinate system (X, Y, Z) or a cylindrical coordinate system (r, θ, z).

In addition, the target may refer to at least one object, but is not limited thereto, and may also refer to a part of an object for reflecting at least a part of the laser emitted from the LiDAR device.

In addition, the LiDAR device according to an embodiment may use the laser that is emitted from the LiDAR device to be reflected from the target, in order to measure the distance to the target.

For example, the LiDAR device according to an embodiment may use the time of flight (TOF) of the laser until the laser is detected since it is emitted, in order to measure the distance to the target.

For a more specific example, the LiDAR device according to an embodiment may measure the distance to the target by using the difference between a time value based on an emitting time of the laser which is emitted and a time value based on a detection time of the laser which is reflected from the target to be detected.

Herein, the time value based on the emitting time of the laser may be obtained by a control unit included in the LiDAR device according to an embodiment.

For example, the time value based on the laser emitting time may be obtained based on the generation time of the trigger signal generated by the control unit included in the LiDAR device according to an embodiment, but is not limited thereto.

In addition, the time value based on the laser emitting time may be obtained by the laser emitting unit included in the LiDAR device according to an embodiment.

For example, the time value based on the laser emitting time may be obtained by detecting the operation of the laser emitting unit included in the LiDAR device according to an embodiment, but is not limited thereto.

Herein, the detection of the operation of the laser emitting unit may mean detection of the flow of current, change in electric field, and the like, in the laser emitting unit, but is not limited thereto.

In addition, the time value based on the emitting time of the laser may be obtained by the detector unit included in the LiDAR device according to an embodiment.

For example, the time value based on the laser emitting time may be obtained based on the time when the laser not reflected from the target is detected by the detector unit included in the LiDAR device according to an embodiment, but is not limited thereto.

Herein, a reference optical path may be provided in which the laser emitted from the laser emitting unit is received by the detector unit, but is not limited thereto.

In addition, a time value based on the detection time of the laser reflected from the target to be detected may be obtained based on the detector unit included in the LIDAR device according to an embodiment.

For example, a time value based on the detection time of the laser is reflected from the target to be detected may be obtained based on the time when the laser reflected from the target is detected by the detector unit included in the LiDAR device according to an embodiment, but is not limited thereto.

In addition, the LiDAR device according to an embodiment may use, in addition to the flight time, a triangulation method, an interferometry method, a phase shift measurement method, and the like, to measure the distance to the target, but is not limited thereto.

The LiDAR device according to an embodiment may be provided in a vehicle. For example, the LiDAR device may be provided in a roof, hood, headlamp, or bumper of the vehicle.

In addition, a plurality of LiDAR devices according to an embodiment may be provided in the vehicle. For example, when two LiDAR devices are provided on the roof of the vehicle, one LiDAR device may serve to observe the front and the other may serve to observe the rear, but the disclosure is not limited thereto. In addition, for example, when two LiDAR devices are provided on the roof of a vehicle, one LiDAR device may serve to observe the left side and the other may serve to observe the right side, but the disclosure is not limited thereto.

In addition, a LiDAR device according to an embodiment may be provided in a vehicle. For example, when a LIDAR device is installed inside a vehicle, it may serve to recognize a driver's gesture while driving, but is not limited thereto. In addition, for example, when the LiDAR device is provided inside or outside a vehicle, it may serve to recognize a driver's face, but is not limited thereto.

A LIDAR device according to an embodiment may be provided in an unmanned aerial vehicle. For example, the LiDAR device may be provided in an unmanned aerial vehicle system (UAV System), a drone, a remote piloted vehicle (RPV), an unmanned aerial vehicle system (UAVs), an unmanned aircraft system (UAS), a remote piloted air/aerial vehicle (RPAV), or a remote piloted aircraft system (RPAS).

In addition, according to an embodiment, a plurality of LiDAR devices may be provided in an unmanned aerial vehicle. For example, when two LiDAR devices are provided in an unmanned aerial vehicle, one LiDAR device may serve to observe the front and the other may serve to observe the rear, but the disclosure is not limited thereto. In addition, for example, when two LiDAR devices are provided on an unmanned aerial vehicle, one LiDAR device may serve to observe the left side and the other may serve to observe the right side, but the disclosure is not limited thereto.

A LIDAR device according to an embodiment may be provided in a robot. For example, the LiDAR device may be provided in a personal robot, a professional robot, a public service robot, other industrial robots, or a manufacturing robot.

In addition, according to an embodiment, a plurality of LiDAR devices may be provided in a robot. For example, when two LiDAR devices are provided in a robot, one LIDAR device may serve to observe the front and the other may serve to observe the rear, but the disclosure is not limited thereto. In addition, for example, when two LiDAR devices are installed in a robot, one LiDAR device may serve to observe the left side and the other may serve to observe the right side, but the disclosure is not limited thereto.

In addition, a LIDAR device according to an embodiment may be provided in a robot. For example, when a LIDAR device is installed in a robot, it may serve to recognize a human face, but is not limited thereto.

In addition, the LiDAR device according to an embodiment may be provided for industrial security. For example, the LiDAR device may be provided in a smart factory for industrial security.

In addition, according to an embodiment, a plurality of LiDAR devices may be provided in a smart factory for industrial security. For example, when two LiDAR devices are provided in a smart factory, one LiDAR device may serve to observe the front and the other may serve to observe the rear, but the disclosure is not limited thereto.

In addition, for example, when two LiDAR devices are provided in a smart factory, one LiDAR device may serve to observe the left side and the other may serve to observe the right side, but the disclosure is not limited thereto.

In addition, a LiDAR device according to an embodiment may be provided for industrial security. For example, when a LIDAR device is provided for industrial security, it may serve to recognize a person's face, but is not limited thereto.

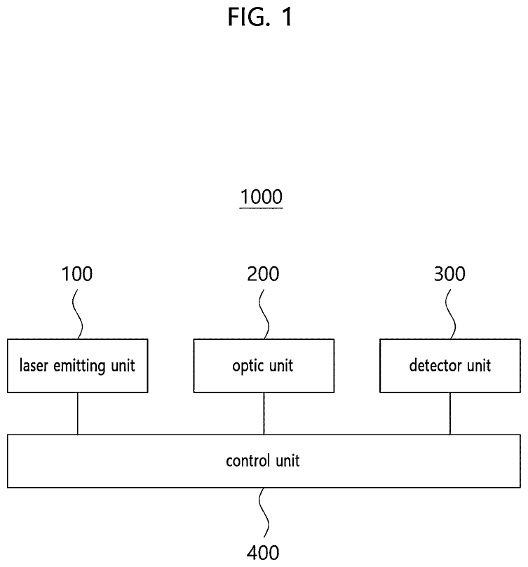

FIG. 1 is a diagram illustrating a LIDAR device according to an embodiment.

Referring to FIG. 1, a LIDAR device 1000 according to an embodiment may include a laser emitting unit 100.

Herein, the laser emitting unit 100 according to an embodiment may generate or emit a laser.

In addition, the laser emitting unit 100 according to an embodiment may include one or more laser emitting elements.

For example, the laser emitting unit 100 according to an embodiment may include a single laser emitting element, and may also include a plurality of laser-emitting elements.

In addition, the laser emitting unit 100 according to an embodiment may be configured as an array in which the plurality of laser-emitting elements is arranged in an array form, but is not limited thereto.

For example, the laser emitting unit 100 according to an embodiment may be implemented as a VCSEL array in which a plurality of vertical cavity surface emitting lasers (VCSELs) is arranged in an array form, but is not limited thereto.

In addition, the laser emitting unit 100 according to an embodiment may include a laser emitting element such as a laser diode (LD), a solid-state laser, a high power laser, a light entitling diode (LED), a vertical cavity surface emitting laser (VCSEL), an external cavity diode laser (ECDL), and the like, but is not limited thereto.

In addition, the wavelength of the laser emitted from the laser emitting unit 100 according to an embodiment may be located in a specific wavelength range.

For example, the wavelength of the laser emitted from the laser emitting unit 100 according to an embodiment may be located in a 905 nm band, may be located in a 940 nm band, and may be located in a 1550 nm band, but is not limited thereto.

Herein, the wavelength band may refer to a band within a certain range based on the center wavelength.

For example, the 905 nm band may refer to a band within a range of 10 nm centered around 905 nm, the 940 nm band may refer to a band within a range of 10 nm centered around 940 nm, and the 1550 nm band may refer to a band within a range of 10 nm centered around 1550 nm, but the disclosure is not limited thereto.

In addition, the wavelength of the laser emitted from the laser emitting unit 100 according to an embodiment may be located in various wavelength ranges.

For example, the wavelength of the first laser emitted from the first laser emitting element included in the laser emitting unit 100 according to an embodiment is located in the 905 nm band, and the wavelength of the second laser emitted from the second laser emitting element included in the laser emitting unit 100 according to an embodiment may be located in the 1550 nm band, but the disclosure is not limited thereto.

In addition, the wavelengths of the laser emitted from the laser emitting unit 100 according to an embodiment may be located within a specific wavelength range, but may be different from each other.

For example, the wavelength of the first laser emitted from the first laser emitting element included in the laser emitting unit 100 according to an embodiment may be located in the 940 nm band, for example, wavelength of 939 nm, and the wavelength of the second laser emitted from the second laser emitting element included in the laser emitting unit 100 according to an embodiment may be located in the 940 nm band, for example, a wavelength of 943 nm, but the disclosure is not limited thereto.

Referring again to FIG. 1, the LiDAR device 1000 according to an embodiment may include an optic unit 200.

Herein, the optic unit may be expressed in various ways, such as a steering unit, a scanning unit, etc., for the purpose of explaining the present disclosure, but is not limited thereto.

The optic unit 200 according to an embodiment may function to change the flight path of the laser.

For example, the optic unit 200 according to an embodiment may function to change the flight path of the laser emitted from the laser emitting unit 100 and, when the laser emitted from the laser emitting unit 100 is reflected from the target, may function to change the flight path of the laser reflected from the target, but is not limited thereto.

In addition, the optic unit 200 according to an embodiment may function to change the flight path of the laser by reflecting the laser.

For example, the optic unit 200 according to an embodiment may function to change the flight path by reflecting the laser emitted from the laser emitting unit 100 and, when the laser emitted from the laser emitting unit 100 is reflected from the target, may function to change the flight path by reflecting the laser reflected from the target, but is not limited thereto.

Herein, the optic unit 200 according to an embodiment may include at least one optical means among different optical means for reflecting the laser.

For example, the optic unit 200 according to an embodiment may include at least one optical means among optical means such as a mirror, a resonance scanner, a MEMS mirror, a voice coil motor (VCM), a polygonal mirror, a rotating mirror, or a Galvano mirror, but is not limited thereto.

In addition, the optic unit 200 according to an embodiment may change the flight path of the laser by refracting the laser.

For example, the optic unit 200 according to an embodiment may function to change the flight path by refracting the laser emitted from the laser emitting unit 100 and, when the laser emitted from the laser emitting unit 100 is reflected from the target, may function to change the flight path by refracting the laser reflected from the target, but is not limited thereto.

Herein, the optic unit 200 according to an embodiment may include at least one optical means among different optical means for refracting the laser.

For example, the optic unit 200 according to an embodiment may include at least one optical means among optical means such as a lens, a prism, a micro lens, a microfluidic lens, or a meta-surface, but is not limited thereto.

In addition, the optic unit 200 according to an embodiment may change the flight path of the laser by changing the phase of the laser.

For example, the optic unit 200 according to an embodiment may function to change the phase of the laser emitted from the laser emitting unit 100 to change the flight path and, when the laser emitted from the laser emitting unit 100 is reflected from the target, function to change the phase of the laser reflected from the target to change the flight path, but is not limited thereto.

Herein, the optic unit 200 according to an embodiment may include at least one optical means among different optical means for changing the phase of the laser.

For example, the optic unit 200 according to an embodiment may include at least one optical means among optical means such as an optical phased array (OPA), a meta lens, or a meta surface, but is not limited thereto.

In addition, the optic unit 200 according to an embodiment may include two or more optic units.

For example, the optic unit 200 according to an embodiment may include a transmitting optic unit for emitting the laser emitted from the laser emitting unit 100 to the scan area of the LiDAR device, and a receiving optic unit for transferring the laser reflected from the target to the detector unit 300, but is not limited thereto.

In addition, for example, the optic unit 200 according to an embodiment may include a first optic unit that changes the flight path of the laser emitted from the laser emitting unit 100 to the direction of the first group, and a second optic unit that changes the flight path of the laser emitted from the laser emitting unit 100 to the direction of the second group, but is not limited thereto.

In addition to the examples described above, the optic unit 200 according to an embodiment may be provided in a combination of different configurations that is likely to expand the scan area of the LiDAR device using the laser emitted from the laser emitting unit 100 according to an embodiment and transfer the laser reflected by the target to the detector unit 300 according to an embodiment.

Referring back to FIG. 1, the LiDAR device 100 according to an embodiment may include a detector unit 300.

Herein, the detector unit may be expressed in various ways, such as a light receiving unit, a receiving unit, a sensor unit, and the like, for the purpose of explaining the present disclosure, but is not limited thereto.

The detector unit 300 according to an embodiment may function to detect a laser.

For example, the detector unit 300 according to an embodiment may detect a laser reflected from a target located within the scan area of the LiDAR device 100 according to an embodiment.

Also, the detector unit 300 according to an embodiment may be arranged to receive the laser and may function to generate an electrical signal based on the received laser.

For example, the detector unit 300 according to an embodiment may be arranged to receive the laser reflected from the target located within the scan area of the LIDAR device 100 according to an embodiment, and may generate an electrical signal based on the same.

Herein, the detector unit 300 according to an embodiment may be arranged to receive the laser reflected from the target located within the scan area of the LiDAR device 100 according to an embodiment through at least one optical means, in which the at least one optical means may be included in the optic unit described above, and may include an optical filter, etc., but is not limited thereto.

In addition, the detector unit 300 according to an embodiment may generate laser detection information based on the generated electrical signal.

For example, the detector unit 300 according to an embodiment may compare a predetermined threshold value with the rising edge, the falling edge, or the median of the rising edge and falling edge in the generated electrical signal, to generate the laser detection information, but is not limited thereto.

In addition, for example, the detector unit 300 according to an embodiment may generate histogram data corresponding to the laser detection information based on the generated electrical signal, but is not limited thereto.

In addition, the detector unit 300 according to an embodiment may determine a laser detection time based on the generated laser detection information.

For example, the detector unit 300 according to an embodiment may determine the laser detection time of the laser based on the laser detection information generated based on the rising edge of the generated electrical signal; determine the laser detection time based on the laser detection information generated based on the falling edge of the generated electrical signal; and determine the laser detection time point based on the laser detection information generated based on the rising edge of the generated electrical signal and the laser detection information generated based on the falling edge, but the disclosure is not limited thereto.

In addition, for example, the detector unit 300 according to an embodiment may determine the laser detection time based on the histogram data generated based on the generated electrical signal, but it is not limited thereto.

For a more specific example, the detector unit 300 according to an embodiment may determine the laser detection time based on the peak of the generated histogram data, the determination of the rising edge and the falling edge based on the predetermined value, and the like, but is not limited thereto.

Herein, the histogram data may be generated based on the electrical signal generated from the detector unit 300 according to an embodiment during at least one scan cycle.

In addition, the detector unit 300 according to an embodiment may include at least one detector element among various detector elements.

For example, the detector unit 300 according to an embodiment may include at least one detector element among detector elements such as a PN photodiode, a phototransistor, a PIN photodiode, an avalanche photodiode (APD), a single-photon avalanche diode (SPAD), a silicon photomultipliers (SiPMs), a comparator, a complementary metal-oxide-semiconductor (CMOS), or a charge coupled device (CCD), but is not limited thereto.

In addition, the detector unit 300 according to an embodiment may include one or more detector elements.

For example, the detector unit 300 according to an embodiment may include a single detector element, and may also include a plurality of detector elements.

In addition, the detector unit 300 according to an embodiment may be configured in an array in which a plurality of detector elements is arranged in an array form, but is not limited thereto.

For example, the detector unit 300 according to an embodiment may be implemented as a SPAD array in which multiple single photon avalanche diodes (SPADs) are arranged in an array form, but is not limited thereto.

Referring again to FIG. 1, the LiDAR device 1000 according to an embodiment may include a control unit 400.

Herein, the control unit may be variously expressed in a controller, etc., in order to explain the present disclosure, but is not limited thereto.

The control unit 400 according to an embodiment may control operations of the laser emitting unit 100, the optic unit 200, or the detector unit 300.

In addition, the control unit 400 according to an embodiment may control an operation of the laser emitting unit 100.

For example, the control unit 400 may control the emitting time point of the laser emitted from the laser emitting unit 100. In addition, the control unit 400 may control the power of the laser emitted from the laser emitting unit 100. In addition, the control unit 400 may control the pulse width of the laser emitted from the laser emitting unit 100. In addition, the control unit 400 may control the period of the laser emitted from the laser emitting unit 100. In addition, when the laser emitting unit 100 includes a plurality of laser emitting elements, the control unit 400 may control the laser emitting unit 100 to allow some of the plurality of laser emitting elements to be operated.

In addition, the control unit 400 according to an embodiment may control an operation of the optic unit 200.

For example, the control unit 400 may control the operation speed of the optic unit 200. Specifically, when the optic unit 200 includes a rotational mirror, the rotational speed of the rotational mirror may be controlled, and when the optic unit 200 includes a MEMS mirror, the repetition cycle of the MEMS mirror may be controlled, but the disclosure is not limited thereto.

In addition, for example, the control unit 400 may control the operation degree of the optic unit 200. Specifically, when the optic unit 200 includes a MEMS mirror, the operation angle of the MEMS mirror may be controlled, but is not limited thereto.

In addition, the control unit 400 according to an embodiment may control an operation of the detector unit 300.

For example, the control unit 400 may control the sensitivity of the detector unit 300. Specifically, the control unit 400 may control the sensitivity of the detector unit 300 by adjusting a predetermined threshold value, but is not limited thereto.

In addition, for example, the control unit 400 may control the operation of the detector unit 300. Specifically, the control unit 400 may control the On/Off of the detector unit 300, and when the control unit 300 includes a plurality of sensor elements, the operation of the detector unit 300 may be controlled to allow some of the sensor elements among the plurality of sensor elements to be operated.

In addition, the control unit 400 according to an embodiment may generate detection information of the laser based on the electrical signal generated from the detector unit 300.

For example, the control unit 400 according to an embodiment may generate the detection information of the laser by comparing the predetermined threshold value with the rising edge, the falling edge, or the median value of the rising edge and falling edge, in the electrical signal generated from the detector unit 300, but is not limited thereto.

In addition, for example, the control unit 400 according to an embodiment may generate histogram data corresponding to the detection information of the laser based on the electrical signal generated from the detector unit 300, but is not limited thereto.

In addition, the control unit 400 according to an embodiment may determine the laser detection time based on the laser detection information generated from the detector unit 300.

For example, the control unit 400 according to an embodiment may determine the laser detection time based on the laser detection information generated based on the rising edge of the electrical signal generated from the detector unit 300; determine the laser detection time point based on the laser detection information generated based on the falling edge of the generated electrical signal; and determine the laser detection time based on the laser detection information generated based on the rising edge of the generated electrical signal and the laser detection information generated based on the falling edge, but the disclosure is not limited thereto.

In addition, for example, the control unit 400 according to an embodiment may determine the laser detection time based on the histogram data generated based on the electrical signal generated from the detector unit 300, but is not limited thereto.

For a more specific example, the control unit 400 according to an embodiment may determine the laser detection time based on the peak of the histogram data generated from the detector unit 300, the determination of the rising edge and falling edge based on the predetermined value, and the like, but is not limited thereto.

Herein, the histogram data may be generated based on the electrical signal generated from the detector unit 300 according to an embodiment, during at least one scan cycle.

In addition, the control unit 400 according to an embodiment may obtain information on the distance to the target based on the determined laser detection time.

For example, the control unit 400 according to an embodiment may obtain information on the distance to the target based on the determined laser emitting time and the determined laser detection time, but is not limited thereto.

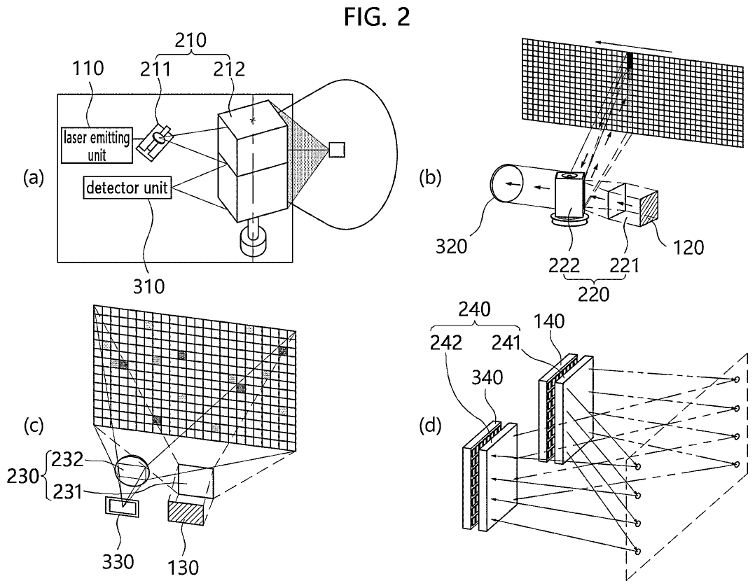

FIG. 2 is a diagram showing various embodiments of a LIDAR device.

Referring to (a) of FIG. 2, a LIDAR device according to an embodiment may include a laser emitting unit 110, an optic unit 210, and a detector unit 310, in which the optic unit 210 may include a nodding mirror 211 that nods within a predetermined range and a multi-faceted mirror 212 that rotates around at least one axis, but is not limited thereto.

Herein, since the above-described contents may be applied to the laser emitting unit 110, the optic unit 210, and the detector unit 310, redundant descriptions will be omitted, and (a) of FIG. 2 is a diagrammatic diagram that is simply used to explain an embodiment of various LiDAR devices, and thus various embodiments of LiDAR devices are not limited to (a) of FIG. 2.

In addition, referring to (b) of FIG. 2, a LIDAR device according to an embodiment may include a laser emitting unit 120, an optic unit 220, and a detector unit 320, in which the optic unit 220 may include at least one lens 221 capable of collimating and steering a laser emitted from the laser emitting unit 120 and a multi-faceted mirror 222 that rotates around at least one axis, but is not limited thereto.

Herein, since the above-described contents may be applied to the laser emitting unit 120, the optic unit 220, and the detector unit 320, redundant descriptions will be omitted, and (b) of FIG. 2 is a diagrammatic diagram that is simply used to explain an embodiment of various LiDAR devices, and thus various embodiments of LiDAR devices are not limited to (b) of FIG. 2.

In addition, referring to (c) of FIG. 2, a LIDAR device according to an embodiment may include a laser emitting unit 130, an optic unit 230, and a detector unit 330, in which the optic unit 230 may include at least one lens 231 capable of collimating and steering a laser emitted from the laser emitting unit 130 and at least one lens 232 capable of transmitting a laser reflected from a target to the detector unit 330, but is not limited thereto.

Herein, since the above-described contents may be applied to the laser emitting unit 130, the optic unit 230, and the detector unit 330, redundant descriptions will be omitted, and (c) of FIG. 2 is a diagrammatic diagram that is simply used to explain an embodiment of various LiDAR devices, and thus various embodiments of LiDAR devices are not limited to (c) of FIG. 2

In addition, referring to (d) of FIG. 2, a LIDAR device according to an embodiment may include a laser emitting unit 140, an optic unit 240, and a detector unit 340, in which the optic unit 240 may include at least one lens 241 capable of collimating and steering a laser emitted from the laser emitting unit 130 and at least one lens 242 capable of transmitting a laser reflected from a target to the detector unit 340, but is not limited thereto.

Herein, since the above-described contents may be applied to the laser emitting unit 140, the optic unit 240, and the detector unit 340, redundant descriptions will be omitted, and (d) of FIG. 2 is a diagrammatic diagram that is simply used to explain an embodiment of various LiDAR devices, and thus various embodiments of LiDAR devices are not limited to (d) of FIG. 2.

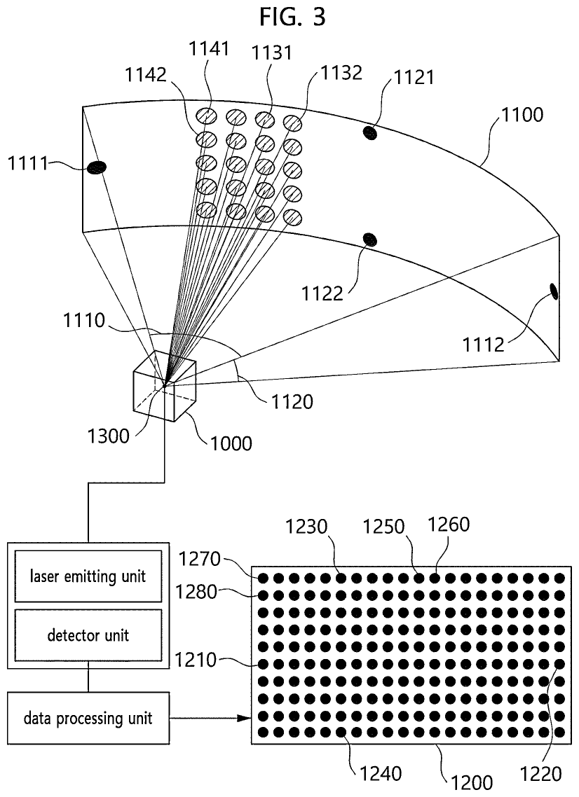

FIG. 3 is a diagram illustrating the operation of the LiDAR device and LiDAR data according to an embodiment.

Referring to FIG. 3, the LiDAR device 1000 according to an embodiment includes a laser emitting unit that emits a laser and a detector unit that detects a laser, in which since the description of the laser emitting unit and the detector unit has been described above, any redundant description will be omitted

In addition, referring to FIG. 3, the data processing unit according to an embodiment may obtain LiDAR data 1200 based on the laser detected by the LiDAR device 1000.

Herein, the data processing unit may be included in the LiDAR device 1000, especially the control unit of the LiDAR device 1000 described above, but may be positioned to be connected to the LiDAR device 1000 through at least one communication method to obtain a signal generated from the detector unit included in the LiDAR device 1000.

In addition, referring to FIG. 3, the LiDAR device 1000 according to an embodiment may form a field of view 1100 by emitting a laser, and may detect a laser reflected within the field of view 1100 to obtain lidar data 1200.

Herein, the field of view 1100 of the LiDAR device 1000 may refer to an area emitted by the laser or an area where the laser may be detected, but is not limited thereto.

In addition, the LiDAR data 1200 may mean various types of data acquired from the LiDAR device 1000, such as point data, point cloud, frame data, and the like that are acquired from the LiDAR device 1000, but is not limited thereto.

Herein, the point data may include distance information, location information, etc., and the point cloud may refer to cluster data of the point data, but is not limited thereto.

In addition, the frame data may refer to a group of the point data, but is not limited thereto.

In addition, the field of view 1100 of the LiDAR device 1000 may include a horizontal field of view 1110 for a horizontal scan range and a vertical field of view 1120 for a vertical scan range.

In addition, the horizontal viewing angle 1110 and the vertical viewing angle 1120 may be defined by the emitted laser.

For example, the horizontal viewing angle 1110 of the LiDAR device 1000 may be defined by a first laser 1111 emitted at a first angle and a second laser 1112 emitted at a second angle, and more specifically, may be defined by a difference between the first angle emitted by the first laser 1111 and the second angle emitted by the second laser 1112, but is not limited thereto.

In addition, for example, the vertical field of view 1120 of the LiDAR device 1000 may be defined by a third laser 1121 emitted at a third angle and a fourth laser 1122 emitted at a fourth angle, and more specifically, may be defined by a difference between the third angle emitted by the third laser 1121 and the second angle emitted by the fourth laser 1122, but is not limited thereto.

However, the horizontal field of view 1110 and the vertical field of view 1120 of the LiDAR device 1000 are not limited to the examples described above, but may be defined by different methods for expressing the area emitted by the laser from the LiDAR device 1000.

In addition, the horizontal field of view 1110 and the vertical field of view 1120 may be defined by the detected laser. More specifically, the horizontal field of view 1110 and the vertical field of view 1120 may be defined by point data generated by the detected laser.

For example, the horizontal field of view 1110 of the LiDAR device 1000 may be defined by the first point data 1210 and the second point data 1220, and more specifically, may be defined by the laser irradiation angle corresponding to the first point data 1210 and the laser irradiation angle corresponding to the second point data 1220, but is not limited thereto.

In addition, for example, the vertical field of view 1120 of the LiDAR device 1000 may be defined by the third point data 1230 and the fourth point data 1240 and, more specifically, may be defined by the laser irradiation angle corresponding to the third point data 1230 and the laser irradiation angle corresponding to the fourth point data 1240, but is not limited thereto.

However, the horizontal field of view 1110 and the vertical field of view 1120 of the LiDAR device 1000 is not limited to the examples described above, and may be defined by different methods for expressing the area in which the LiDAR device 1000 may detect the laser.

In addition, referring to FIG. 3, the laser forming the field of view 1100 of the LiDAR device 1000 according to an embodiment may be emitted to have angular resolution.

Herein, the angular resolution may include horizontal angular resolution for the resolution in the horizontal direction and vertical angular resolution for the resolution in the vertical direction.

In addition, the horizontal angular resolution and the vertical angular resolution may be defined by the emitted laser.

For example, the horizontal angular resolution of the LiDAR device 1000 may be defined by a fifth laser 1131 emitted at a fifth angle and a sixth laser 1132 emitted at a sixth angle and, more specifically, may be defined by a difference between the fifth angle emitted by the fifth laser 1131 and the sixth angle emitted by the sixth laser 1132, but is not limited thereto.

In addition, for example, the vertical angular resolution of the LiDAR device 1000 may be defined by a seventh laser 1141 emitted at the seventh angle and an eighth laser 1142 emitted at the eighth angle, and more specifically, may be defined by the difference between the seventh angle emitted by the seventh laser 1141) and the eighth angle emitted by the eighth laser 1142, but is not limited thereto.

However, the horizontal angular resolution and the vertical angular resolution of the LiDAR device 1000 is not limited to the examples described above, but may be defined by different methods for expressing the angular resolution capable of distinguishing the object to be detected.

In addition, referring to FIG. 3, the LiDAR data 1200 obtained from the LIDAR device 1000 according to an embodiment may include point data having angular resolution.

Herein, the angular resolution may include horizontal angular resolution for the resolution in the horizontal direction and vertical angular resolution for the resolution in the vertical direction.

In addition, the horizontal angular resolution and the vertical angular resolution may be defined by the detected laser. More specifically, the horizontal angular resolution and the vertical angular resolution may be defined by the point data generated by the detected laser.

For example, the horizontal angular resolution of the LiDAR device 1000 may be defined by the fifth point data 1250 and the sixth point data 1260, and more specifically, may be defined by the laser irradiation angle corresponding to the fifth point data 1250 and the laser irradiation angle corresponding to the sixth point data 1260, but is not limited thereto.

In addition, for example, the vertical angular resolution of the LiDAR device 1000 may be defined by the seventh point data 1270 and the eighth point data 1280, and more specifically, may be defined by the laser irradiation angle corresponding to the seventh point data 1270 and the laser irradiation angle corresponding to the eighth point data 1280, but is not limited thereto.

However, the horizontal angular resolution and the vertical angular resolution of the LiDAR device 1000 is not limited to the examples described above, but may be defined by different methods for expressing the angular resolution capable of distinguishing the objects to be detected.

In addition, the lasers emitted from the LiDAR device 1000 may each have a size and a divergence angle.

For example, each laser emitted from the LiDAR device 1000 may have a major axis length, a minor axis length, and a divergence angle, but is not limited thereto.

In addition, each point data included in the LiDAR data 1200 may include distance information.

In addition, an optical origin 1300 may be defined for the LiDAR device 1000.

Herein, the optical origin 1300 may refer to an origin of a coordinate system to express the LiDAR data described above.

In addition, the optical origin 1300 may refer to an origin defined when it is assumed that the laser emitted from the LiDAR device 1000 is emitted from one point.

In addition, the optical origin 1300 may refer to an origin of distance measurement to measure a distance using a laser in the LiDAR device 1000.

In addition, the optical origin 1300 may refer to an origin used for describing point data acquired from the LiDAR device 1000.

In addition, the optical origin 1300 may refer to an optical origin physically derived, but is not limited thereto, and may refer to an optical origin artificially assigned to the LIDAR device 1000, but is not limited thereto.

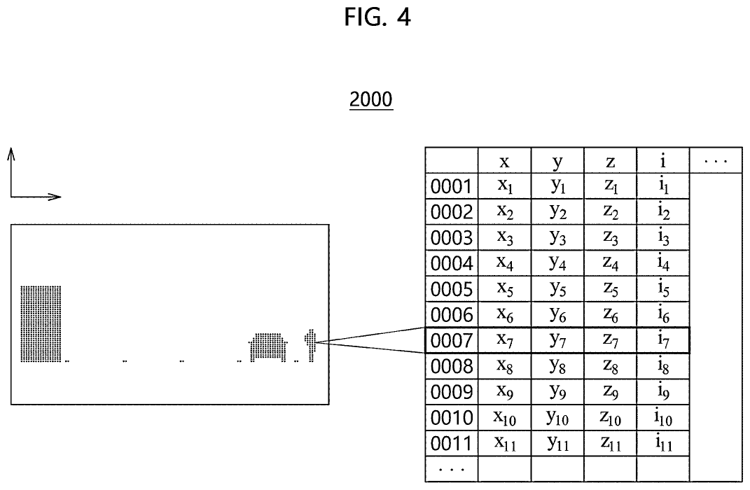

FIG. 4 is a diagram illustrating LiDAR data according to an embodiment.

The lidar data according to an embodiment may be expressed in different formats such as a point cloud, a depth map, an intensity map, and the like.

Herein, the point cloud may be a format displayed by converting information on each measurement point into location information, in which the point cloud according to an embodiment may include location coordinate values x, y, and z and an intensity value I, which are acquired based on information on an angle and a distance at which the laser is emitted or acquired, but is not limited thereto.

In addition, the depth map may be a format including two-dimensional pixel location information and distance information on each measurement point, and the depth map according to an embodiment may include pixel values x and y, and a distance value D acquired based on information on an angle at which the laser is emitted or acquired, but is not limited thereto.

In addition, the intensity map may be in a format that includes 2D pixel location information and intensity information for each measurement point, in which the intensity map according to an embodiment may include pixel values x and y, and an intensity value I, which are acquired based on information on an angle at which the laser is emitted or acquired, but is not limited thereto.

In addition, although the LIDAR data may be acquired in different formats in addition to the examples described above, it will be described hereinafter based on the LIDAR data acquired in the form of the point cloud, for convenience of explanation.

Referring to FIG. 4, the LIDAR data according to an embodiment may include point cloud data 2000.

In addition, the point cloud data 2000 according to an embodiment may include a plurality of point data.

In addition, each of the plurality of point data according to an embodiment may include, but is not limited to, position coordinate values x, y, and z, and an intensity value i.

Herein, the position coordinate values included in each of the plurality of point data may be obtained based on a distance value.

For example, the position coordinate values included in each of the plurality of point data may be obtained based on an angle (or coordinate) value at which the laser is emitted and a distance value which is obtained based on the emitted laser, but is not limited thereto.

In addition, for example, the position coordinate value included in each of the plurality of point data may be obtained based on a coordinate value of the detector which has acquired the laser and a distance value which is obtained based on the acquired laser, but is not limited thereto.

In addition, the intensity value included in each of the plurality of point data may be obtained based on an electrical signal obtained from a detector unit.

For example, the intensity value included in each of the plurality of point data may be obtained based on characteristics such as the size and width of the electrical signal obtained from the detector unit, but is not limited thereto, and may be obtained by different algorithms for the electrical signal obtained from the detector unit.

In addition, for example, the intensity value included in each of the plurality of point data may be acquired based on the histogram data generated based on the electrical signal acquired from the detector unit, but is not limited thereto.

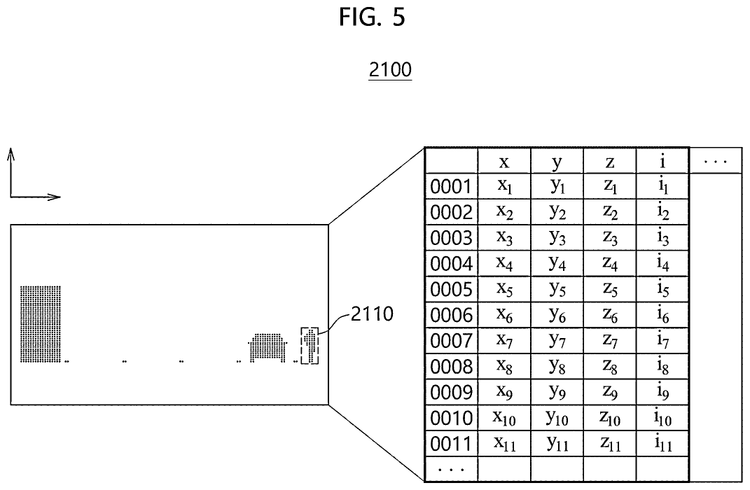

FIG. 5 is a diagram illustrating lidar data according to an embodiment.

Referring to FIG. 5, lidar data according to an embodiment may include point cloud data 2100.

Herein, since the above-described contents may be applied to the point cloud data 2100, redundant descriptions will be omitted.

The point cloud data 2100 according to an embodiment may include at least one sub-point data set 2110.

Herein, the at least one sub-point data set 2110 may refer to a set of point data grouped by a specific rule or algorithm, etc.

For example, the at least one sub-point data set 2110 may refer to a set of point data grouped through human input, but is not limited thereto.

In addition, for example, the at least one sub-point data set 2110 may refer to a set of point data grouped by a segmentation algorithm for the same object, but is not limited thereto.

In addition, for example, the at least one sub-point data set 2110 may refer to a set of point data grouped by a clustering algorithm, but is not limited thereto.

In addition, for example, the at least one sub-point data set 2110 may refer to a set of point data grouped by a machine learning model, but is not limited thereto.

In addition, for example, the at least one sub-point data set 2110 may refer to a set of point data grouped by a deep learning model, but is not limited thereto.

In addition, the lidar data processing unit according to an embodiment may obtain attribute data for the at least one sub-point data set 2110 described above.

For example, the lidar data processing unit according to an embodiment may obtain at least one attribute data for the at least one sub-point data set 2110 according to a human input, but is not limited thereto.

In addition, for example, the lidar data processing unit according to an embodiment may obtain at least one attribute data for the at least one sub-point data set 2110 using a specific algorithm, but is not limited thereto.

In addition, for example, the lidar data processing unit according to an embodiment may obtain at least one attribute data for the at least one sub-point data set 2110 using a machine learning model, but is not limited thereto.

In addition, for example, the lidar data processing unit according to an embodiment may obtain at least one attribute data for the at least one sub-point data set 2110 using a deep learning model, but is not limited thereto.

In addition, the above-described machine learning model or deep learning model may include at least one artificial neural network layer (ANN).

For example, the above-described machine learning model or deep learning model may include at least one artificial neural network layer among various artificial neural network layers, such as a feedforward neural network, a radial basis function network, a Kohonen self-organizing network (SOM), a deep neural network (DNN), a convolutional neural network (CNN), a recurrent neural network (RNN), a long short term memory network (LSTM), or gated recurrent units (GRUs), but is not limited thereto.

In addition, the at least one artificial neural network layer included in the above-described machine learning model or deep learning model may be designed to use the same or different activation functions.

Herein, the above activation function may include, but is not limited to, a sigmoid function, a hyperbolic tangent function, a Relu function (rectified linear unit function), a leaky Relu function, an ELU function (exponential linear unit function), a softmax function, and the like, and may include different activation functions (including custom activation functions) for outputting a result value or passing it to another artificial neural network layer.

In addition, the above-described machine learning model or deep learning model may be trained using at least one loss function.

Herein, the at least one loss function may include, but is not limited to, mean squared error (MSE), root mean squared error (RMSE), binary crossentropy, categorical crossentropy, sparse categorical crossentropy, and the like, and may include different functions (including custom loss functions) for calculating a difference between a predicted result value and an actual result value.

In addition, the above-described machine learning model or deep learning model may be trained using at least one optimizer.

Herein, the optimizer may be used to update relationship parameters between the input value and the result value.

Herein, the at least one optimizer may include, but is not limited to, Gradient Descent, Batch Gradient Descent, Stochastic Gradient Descent, Mini-batch Gradient Descent, Momentum, AdaGrad, RMSProp, AdaDelta, Adam, NAG, NAdam, RAdam, AdamW, and the like.

Hereinafter, the acquired attribute data will be described in more detail.

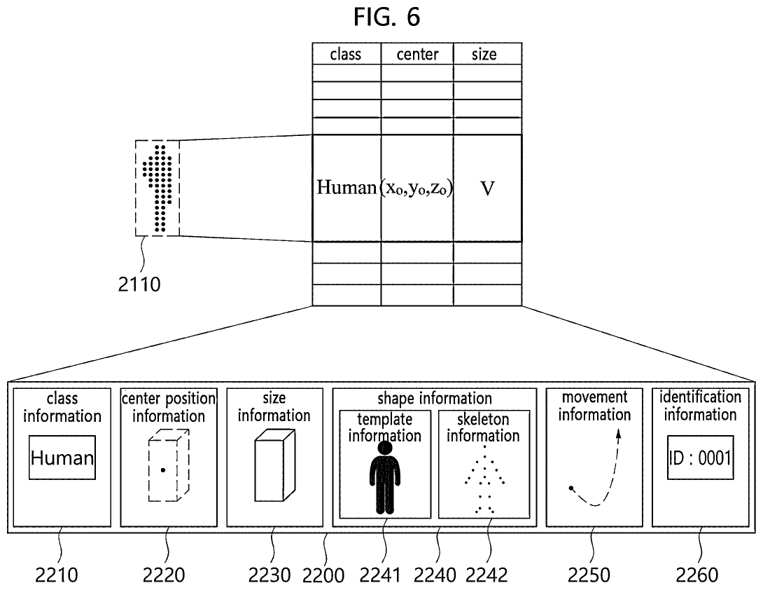

FIG. 6 is a diagram illustrating information included in attribute data according to an embodiment.

Referring to FIG. 6, a lidar data processing unit according to an embodiment may obtain at least one attribute data 2200 for a sub-point data set 2110 according to an embodiment.

Herein, the at least one attribute data 2200 may include, but is not limited to, class information 2210, center location information 2220, size information 2230, shape information 2240, movement information 2250, and identification information 2260 of an object, which are indicated by the sub-point data set 2110.

In addition, the same algorithm or model may be used, or different algorithms or models may be used, to obtain each attribute data included in the at least one attribute data 2200.

In addition, the at least one attribute data 2200 may be acquired based on point cloud data included in one frame data.

For example, the attribute data such as class information 2210, center location information 2220, size information 2230, and shape information 2240 of the object included in the at least one attribute data 2200 may be acquired based on point cloud data included in one frame data, but is not limited thereto.

In addition, the at least one attribute data 2200 may be acquired based on point cloud data included in the plurality of frame data.

For example, the attribute data such as movement information 2250 and identification information 2260 included in the at least one attribute data 2200 may be acquired based on the point cloud data included in the plurality of frame data, but is not limited thereto.

In addition, although the description has been made based on LiDAR data acquired in the form of the point cloud referring to FIGS. 4 to 6, the above-described contents may also be applied to the LiDAR data acquired in the form of a depth map, an intensity map, and the like, in addition to the point cloud format as described above.

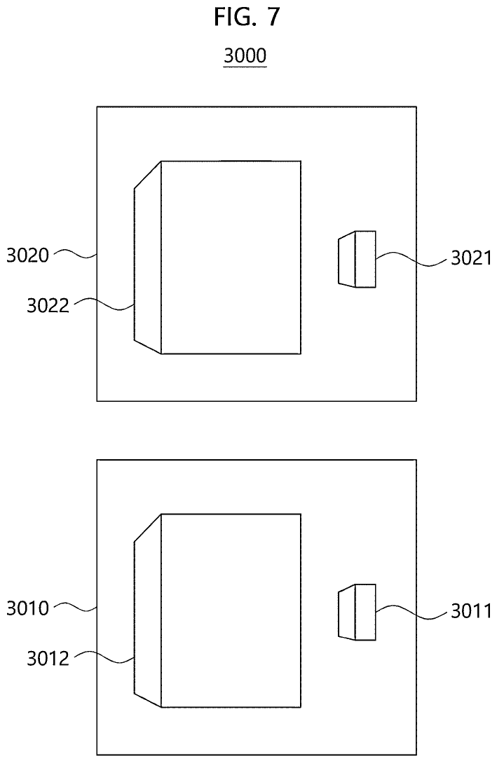

FIG. 7 is a diagram illustrating a LIDAR device according to an embodiment.

Referring to FIG. 7, a LiDAR device 3000 according to an embodiment may include a transmission module 3010 and a receiving module 3020.

In addition, the transmission module 3010 may include a laser emitting array 3011 and a first lens assembly 3012, but is not limited thereto.

Herein, since the above-described contents of the laser emitting unit and the like may be applied to the laser emitting array 3011, any redundant description will be omitted.

In addition, the first lens assembly 3012 may be conveniently referred to as a transmission lens assembly, a transmission optic, a transmission optic unit, a transmission optic module, an emitting optic, an emitting optic unit, an emitting optic module, and the like, but is not limited thereto.

In addition, the laser emitting array 3011 may emit at least one laser. For example, the laser emitting array 3011 may emit multiple lasers, but is not limited thereto.

In addition, the laser emitting array 3011 may emit at least one laser at a first wavelength. For example, the laser emitting array 3011 may emit at least one laser at a wavelength of 940 nm, and may emit multiple lasers at a wavelength of 940 nm, but is not limited thereto.

Herein, the first wavelength may be a wavelength range including an error range. For example, the first wavelength may indicate a wavelength range from 935 nm to 945 nm, which is a wavelength of 940 nm with an error range of 5 nm, but is not limited thereto.

In addition, the laser emitting array 3011 may emit at least one laser at the same time. For example, the laser emitting array 3011 may emit at least one laser at the same time, such as emitting a first laser at a first time, or emitting a first and a second laser at a second time, and so on.

In addition, the first lens assembly 3012 may include at least two or more lens layers. For example, the first lens assembly 3012 may include at least four lens layers, but is not limited thereto.

In addition, the first lens assembly 3012 may collimate the laser emitted from the laser emitting array 3011. For example, the first lens assembly 3012 may change the divergence of the first laser by collimating the first laser emitted from the laser emitting array 3011, but is not limited thereto.

In addition, the first lens assembly 3012 may steer the laser emitted from the laser emitting array 3011. For example, the first lens assembly 3012 may steer the first laser emitted from the laser emitting array 3011 in a first direction, and may steer the second laser emitted from the laser emitting array 3011 in a second direction, but is not limited thereto.

In addition, the first lens assembly 3012 may steer the plurality of lasers emitted from the laser emitting array 3011 to emit the plurality of lasers at different angles within a range of (x) degrees to (y) degrees. For example, the first lens assembly 3012 may steer the first laser emitted from the laser emitting array 3011 in a first direction to emit the first laser at (x) degrees, and may steer the second laser in the second direction to emit the second laser emitted from the laser emitting array 3011 at (y) degrees, but the disclosure is not limited thereto.

In addition, the receiving module 3020 may include, but is not limited to, a laser detecting array 3021 and a second lens assembly 3022.

Herein, since the above-described contents of the detector unit and the like may be applied to the laser detecting array 3021, redundant descriptions will be omitted.

In addition, the second lens assembly 3022 may be referred to as a receiving lens assembly, a receiving optic, a receiving optic unit, a receiving optic module, a receiving optic, a receiving optic unit, a receiving optic module, and the like, depending on convenience, but is not limited to these.

In addition, the laser detecting array 3021 may detect at least one laser. For example, the laser detecting array 3021 may detect multiple lasers.

In addition, the laser detecting array 3021 may include a plurality of detectors. For example, the laser detecting array 3021 may include a first detector and a second detector, but is not limited thereto.

In addition, each of the plurality of detectors included in the laser detecting array 3021 may receive different lasers. For example, the first detector included in the laser detecting array 3021 may receive a first laser received in a first direction, and the second detector may receive a second laser received in a second direction, but is not limited thereto.

In addition, the laser detecting array 3021 may detect at least a portion of the laser emitted from the transmission module 3010. For example, the laser detecting array 3021 may detect at least a part of the first laser and at least a part of the second laser, which are emitted from the transmission module 3010, but is not limited thereto.

In addition, the second lens assembly 3022 may transmit the laser emitted from the transmission module 3010 to the laser detecting array 3021. For example, the second lens assembly 3022 may transfer the first laser into the laser detecting array 3021 when the first laser emitted from the transmission module 3010 in the first direction is reflected from the target located in the first direction, and transfer the second laser into the laser detecting array 3021 when the second laser emitted in the second direction is reflected from the target located in the second direction, but is not limited thereto.

In addition, the second lens assembly 3022 may distribute the laser emitted from the transmission module 3010 into at least two different detectors. For example, the second lens assembly 3022 may distribute the first laser into the first detector included in the laser detecting array 3021 when the first laser emitted from the transmission module 3010 in a first direction is reflected from a target located in the first direction; and

distribute the second laser into the second detector included in the laser detecting array 3021 when the second laser emitted in a second direction is reflected from a target located in the second direction, but is not limited thereto.

In addition, the laser emitting array 3011 and the laser detecting array 3021 may at least partially match each other. For example, the first laser emitted from a first laser emitting element included in the laser emitting array 3011 may be detected by the first detector included in the laser detecting array 3021; and the second laser emitted from the second laser emitting element included in the laser emitting array 3011 may be detected by the second detector included in the laser detecting array 3021, but is not limited thereto.

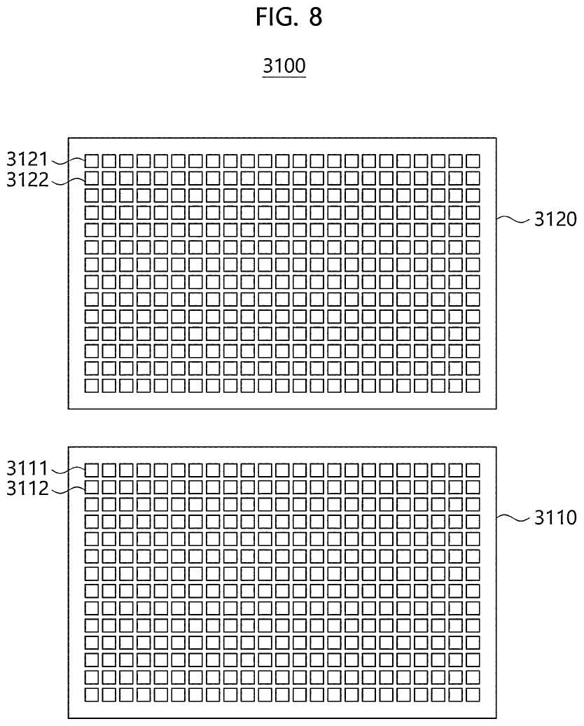

FIG. 8 is a diagram illustrating a laser emitting array and a laser detecting array included in a LIDAR device according to an embodiment.

Referring to FIG. 8, a LIDAR device 3100 according to an embodiment may include a laser emitting array 3110 and a laser detecting array 3120.

Herein, since the above-described contents may be applied to the laser emitting array 3110 and the laser detecting array 3120, redundant descriptions will be omitted.

The laser emitting array 3110 may include a plurality of laser emitting units.

For example, the laser emitting array 3110 may include a first laser emitting unit 3111 and a second laser emitting unit 3112.

In addition, the laser emitting array 3110 may be an array in which the plurality of laser emitting units are arranged in a two-dimensional matrix form.

For example, the laser emitting array 3110 may be an array in which the plurality of laser emitting units are arranged in a two-dimensional matrix form having M rows and N columns, but is not limited thereto.

In addition, each of the plurality of laser emitting units may include at least one laser emitting element.

For example, the first laser emitting unit 3111 included in the plurality of laser emitting units may include one laser emitting element, and the second laser emitting unit 3112 may include one laser emitting element, but is not limited thereto.

In addition, for example, the first laser emitting unit 3111 included in the plurality of laser emitting units may include two or more laser emitting elements, and the second laser emitting unit 3112 may include two or more laser emitting elements, but is not limited thereto.

In addition, the lasers emitted from each of the plurality of laser emitting units may be emitted in different directions.

For example, the first laser emitted from the first laser emitting unit 3111 included in the plurality of laser emitting units may be emitted in the first direction, and the second laser emitted from the second laser emitting unit 3112 may be emitted in the second direction, but is not limited thereto.

In addition, the lasers emitted from each of the plurality of laser emitting units may not overlap each other at the target position.

For example, the first laser emitted from the first laser emitting unit 3111 included in the plurality of laser emitting units may not overlap with the second laser emitted from the second laser emitting unit 3112 at a distance of 100 m, but is not limited thereto.

The laser detecting array 3120 may include a plurality of detecting units.

For example, the laser detecting array 3120 may include a first detecting unit 3121 and a second detecting unit 3122.

In addition, the laser detecting array 3120 may be an array in which a plurality of detecting units is arranged in a two-dimensional matrix form.

For example, the laser detecting array 3120 may be an array in which a plurality of detecting units is arranged in a two-dimensional matrix form having M rows and N columns, but is not limited thereto.

In addition, each of the plurality of detecting units may include at least one laser detecting element.

For example, the first detecting unit 3121 included in the plurality of detecting units may include one laser detecting element, and the second detecting unit 3122 included in the plurality of detecting units may include one laser detecting element, but is not limited thereto.

In addition, for example, the first detecting unit 3121 included in the plurality of detecting units may include two or more laser detecting elements, and the second detecting unit 3122 included in the plurality of detecting units may include two or more laser detecting elements, but is not limited thereto.

In addition, each of the plurality of detecting units may detect lasers emitted in different directions.

For example, the first detecting unit 3121 included in the plurality of laser emitting units may detect the first laser emitted in the first direction, and the second detecting unit 3122 may detect the second laser emitted in the second direction, but is not limited thereto.

In addition, the plurality of detecting units may each detect lasers emitted from laser emitting units arranged to correspond each other.

For example, the first detecting unit 3121 included in the plurality of detecting units may detect the first laser emitted from the first laser emitting unit 3111 arranged to correspond to the first detecting unit 3121; and the second detecting unit 3122 may detect the second laser emitted from the second laser emitting unit 3112 arranged to correspond to the second detecting unit 3122, but is not limited thereto.

In addition, each of the plurality of detecting units may detect the laser emitted from at least two laser emitting units depending on the position of the target.

For example, the second detecting unit 3122 included in the plurality of detecting units may detect the second laser emitted from the second laser emitting unit 3112 when the target is located in the first distance range; and detect the first laser emitted from the first laser emitting unit 3111 when the target is located in the second distance range, but is not limited thereto.

In addition, at least one detection value may be generated based on a signal acquired from each of the plurality of detecting units.

Herein, the detection value may include, but is not limited to, a depth value (distance value), an intensity value, and the like.

In addition, the coordinate of the detection value may be determined based on the arrangement of each of the plurality of detecting units.

For example, the first detecting unit 3121 included in the plurality of detecting units may be arranged at a position of (1,1) in the laser detecting array, and the coordinate of the first detecting value generated based on the signal acquired from the first detecting unit 3121 may be determined as (1,1), but is not limited thereto.

In addition, for example, the second detecting unit 3122 included in the plurality of detecting units may be arranged at a position of (2,1) in the laser detecting array, and the coordinate of the second detecting value generated based on the signal acquired from the second detecting unit 3122 may be determined as (2,1), but is not limited thereto.

In addition, although the coordinate values directly corresponding to the positions of each of the plurality of detecting units are calculated in the above-described examples, the content of the present disclosure is not limited thereto, and may include various rules by which the coordinates of the detecting value may be determined based on the arrangement of each of the plurality of detecting units.

In addition, point data may be generated based on the detecting value and the coordinates of the detecting value.

For example, the first point data may be generated based on a first value generated based on a signal acquired form the first detecting unit 3121 included in the plurality of detecting units, and the first coordinate value which is the coordinate value of the first detection value, and the first point data may include, but is not limited to, a three-dimensional position coordinate value and an intensity value.

In addition, for example, the second point data may be generated based on the second detection value generated based on a signal acquired from the second detecting unit 3122 included in the plurality of detecting units and a second coordinate value which is a coordinate value of the second detection value, and the second point data may include, but is not limited to, a three-dimensional position coordinate value and an intensity value.

In addition, the laser emitting array 3110 and the laser detecting array 3120 may be arranged as arrays having the same dimensions to each other.

For example, the laser emitting array 3110 and the laser detecting array 3120 may be arranged as an array in which the plurality of laser emitting units and the plurality of detecting units have M rows and N columns, respectively, but are not limited thereto.

In addition, the laser emitting array 3110 and the laser detecting array 3120 may be arranged as arrays having different dimensions from each other.

For example, the laser emitting array 3110 may be arranged as an array having M rows and N columns, and the laser detecting array 3120 may be arranged as an array having M+3 rows and N columns, but the disclosure is not limited thereto.

In addition, the number of laser emitting units included in the laser emitting array 3110 may be the same as the number of detecting units included in the laser detecting array 3120.

For example, the laser emitting array 3110 may include M*N laser emitting units, and the laser detecting array 3120 may include M*N detecting units, but the disclosure is not limited thereto.

In addition, the number of laser emitting units included in the laser emitting array 3110 may be different from the number of detecting units included in the laser detecting array 3120.

For example, the laser emitting array 3110 may include M*N laser emitting units, and the laser detecting array 3120 may include (M+3) *N detecting units, but the disclosure is not limited thereto.

In addition, for example, the laser emitting array 3110 may include (M*N)/2 laser emitting units, and the laser detecting array 3120 may include M*N detecting units, but the disclosure is not limited thereto.

In addition, for example, the laser emitting array 3110 may include (M*N)/2 laser emitting units, and the laser detecting array 3120 may include (M+3) *N detecting units, but the disclosure is not limited thereto.

In addition, the number of laser emitting elements included in each of the plurality of laser emitting units included in the laser emitting array 3110 may be different from the number of laser detecting elements included in each of the plurality of laser detecting units included in the laser detecting array 3120.

For example, when the number of laser emitting elements included in the first laser emitting unit 3111 is one, the number of laser detecting elements included in the first laser detecting unit 3121 may be nine, but is not limited thereto.

In addition, for example, when the number of laser emitting elements included in the second laser emitting unit 3112 is one, the number of laser detecting elements included in the second laser detecting unit 3122 may be nine, but is not limited thereto.

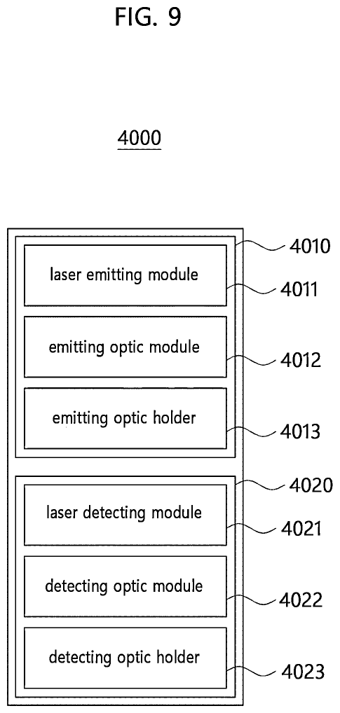

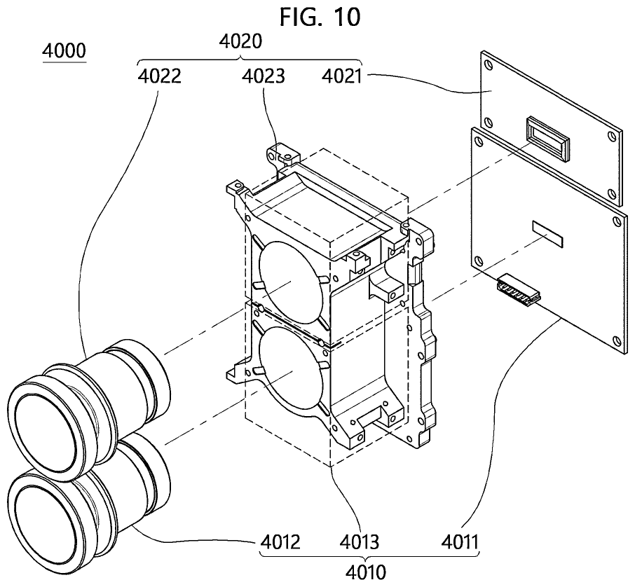

FIG. 9 and FIG. 10 are diagrams illustrating a LIDAR device according to an embodiment.

Referring to FIG. 9 and FIG. 10, the LiDAR device 4000 according to an embodiment may include a transmission module 4010 and a receiving module 4020.

In addition, referring to FIG. 9 and FIG. 10, the transmission module 4010 may include a laser emitting module 4011, an emitting optic module 4012, and an emitting optic holder 4013.

Herein, the laser emitting module 4011 may include a laser emitting array, and since the above-described contents may be applied to the laser emitting array, redundant descriptions will be omitted.

In addition, the emitting optic module 4012 may include a lens assembly, and since the above-described contents of the first lens assembly may be applied to the lens assembly, redundant descriptions will be omitted.

In addition, the emitting optic holder 4013 may be positioned between the laser emitting module 4011 and the emitting optic module 4012.

For example, the emitting optic holder 4013 may be positioned between the laser emitting module 4011 and the emitting optic module 4012 in order to hold the relative positional relationship between the laser emitting module 4011 and the emitting optic module 4012, but is not limited thereto.

In addition, the emitting optic holder 4013 may be formed to hold the movement of the emitting optic module 4012.

For example, the emitting optic holder 4013 may be formed to include a hole into which at least a part of the emitting optic module 4012 is inserted so that movement of the emitting optic module 4012 is limited, but is not limited thereto.

In addition, with reference to FIGS. 9 and 10, the receiving module 4020 according to an embodiment may include a laser detecting module 4021, a detecting optic module 4022, and a detecting optic holder 4023.

Herein, the laser detecting module 4021 may include a laser detecting array, and since the above-described contents may be applied to the laser detecting array, redundant descriptions will be omitted.

In addition, the detecting optic module 4022 may include a lens assembly, and since the above-described contents of the second lens assembly may be applied to the lens assembly, redundant descriptions will be omitted.

In addition, the detecting optic holder 4023 may be positioned between the laser detecting module 4021 and the detecting optic module 4022.

For example, the detecting optic holder 4023 may be positioned between the laser detecting module 4021 and the detecting optic module 4022 to hold relative positional relationship between the laser detecting module 4021 and the detecting optic module 4022, but is not limited thereto.

In addition, the detecting optic holder 4023 may be formed to hold movement of the detecting optic module 4022.

For example, the detecting optic holder 4023 may be formed to include a hole into which at least a part of the detecting optic module 4022 is inserted so that the movement of the detecting optic module 4022 is limited, but is not limited thereto.

In addition, the emitting optic holder 4013 and the detecting optic holder 4023 may be integrally formed.

For example, the emitting optic holder 4013 and the detecting optic holder 4023 may be integrally formed so that at least a part of the emitting optic module 4012 and the detecting optic module 4013 are inserted into each of two holes of one optic holder, but the invention is not limited thereto.

In addition, the emitting optic holder 4013 and the detecting optic holder 4023 may not be physically separated from each other, and may conceptually mean a first part and a second part of one optic holder, but the invention is not limited thereto.

In addition, FIG. 10 is a diagram illustrating an embodiment of the LiDAR device of FIG. 9, and the contents described herein referring to FIG. 9 are not limited to the shape illustrated in FIG. 10.

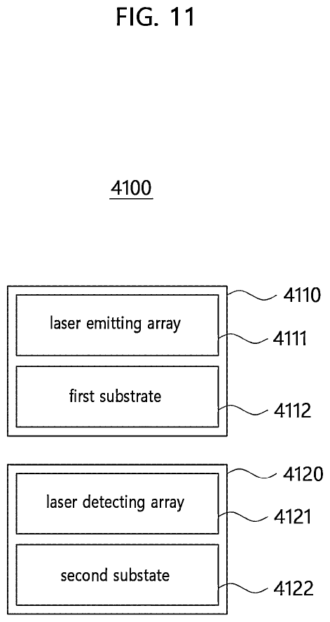

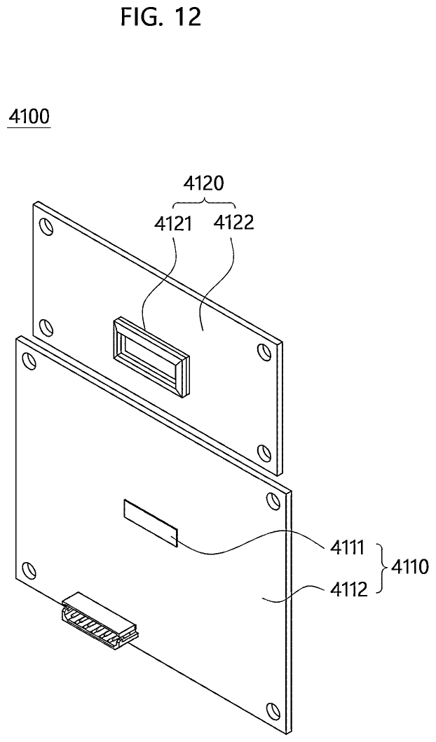

FIG. 11 and FIG. 12 are diagrams illustrating a laser emitting module and a laser detecting module according to an embodiment.

Referring to FIG. 11 and FIG. 12, a LIDAR device 4100 according to an embodiment may include a laser emitting module 4110 and a laser detecting module 4120.

In addition, referring to FIG. 11 and FIG. 12, a laser emitting module 4110 according to an embodiment may include a laser emitting array 4111 and a first substrate 4112.

Herein, since the above-described contents may be applied to the laser emitting array 4111, redundant descriptions will be omitted.

The laser emitting array 4111 according to an embodiment may be provided in the form of a chip in which a plurality of laser emitting units is arranged in an array form, but is not limited thereto.

For example, the laser emitting array 4111 may be provided in the form of a laser emitting chip, but is not limited thereto.

In addition, the laser emitting array 4111 may be positioned on the first substrate 4112, but is not limited thereto.

In addition, the first substrate 4112 may include a laser emitting driver for controlling the operation of the laser emitting array 4111, but is not limited thereto.

In addition, referring to FIGS. 11 and 12, a laser detecting module 4120 according to an embodiment may include a laser detecting array 4121 and a second substrate 4122.

Herein, since the above-described contents may be applied to the laser detecting array 4121, redundant descriptions will be omitted.

The laser detecting array 4121 according to an embodiment may be provided in the form of a chip in which a plurality of laser detecting units is arranged in an array form, but is not limited thereto.

For example, the laser detecting array 4121 may be provided in the form of a laser detecting chip, but is not limited thereto.

In addition, the laser detecting array 4121 may be located on the second substrate 4122, but is not limited thereto.

In addition, the second substrate 4122 may include a laser detecting driver for controlling the operation of the laser detecting array 4121, but is not limited thereto.

In addition, the first substrate 4112 and the second substrate 4122 may be provided separately from each other as illustrated in FIG. 11, but is not limited thereto, and may be provided as a single substrate.

In addition, FIG. 12 is a diagram illustrating an embodiment of the LiDAR device of FIG. 11, and the contents described herein referring to FIG. 11 are not restricted by the shape illustrated in FIG. 12.

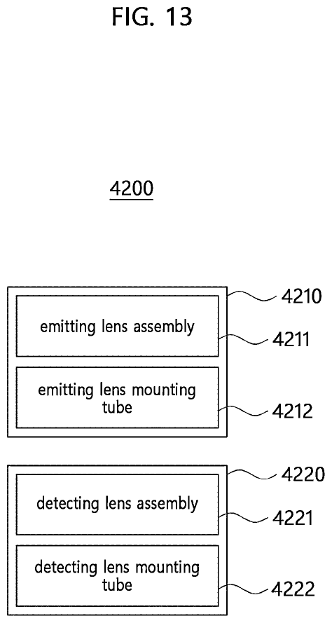

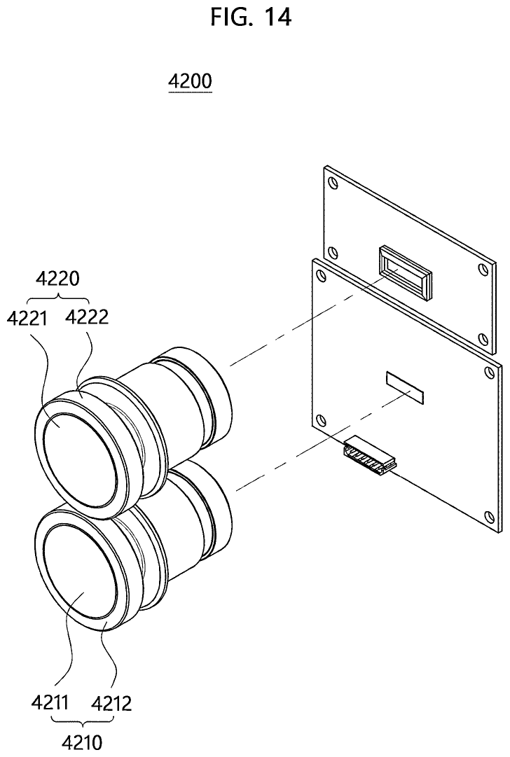

FIG. 13 and FIG. 14 are diagrams illustrating an emitting lens module and a detecting lens module according to an embodiment.

Referring to FIG. 13 and FIG. 14, a LIDAR device 4200 according to an embodiment may include an emitting lens module 4210 and a detecting lens module 4220.

In addition, referring to FIG. 13 and FIG. 14, an emitting lens module 4210 according to an embodiment may include an emitting lens assembly 4211 and an emitting lens mounting tube 4212.

Herein, since the above-described contents may be applied to the emitting lens assembly 4211, redundant descriptions will be omitted.

An emitting lens assembly 4211 according to an embodiment may be placed within the emitting lens mounting tube 4212.

In addition, the emitting lens mounting tube 4212 may refer to a tube surrounding the emitting lens assembly 4211, but is not limited thereto.

In addition, referring to FIGS. 13 and 14, a detecting lens module 4220 according to an embodiment may include a detecting lens assembly 4221 and a detecting lens mounting tube 4222.

Herein, since the above-described contents may be applied to the detecting lens assembly 4221, redundant description will be omitted.

The detecting lens assembly 4221 according to an embodiment may be placed in the detecting lens mounting tube 4222.

In addition, the detecting lens mounting tube 4222 may refer to a tube surrounding the detecting lens assembly 4221, but is not limited thereto.

In addition, referring to FIG. 14, the emitting optic module 4210 may be placed to be aligned with the above-described laser emitting module.

Herein, the emitting optic module 4210 being arranged to be aligned with the above-described laser emitting module may mean that it is arranged to have a physically predetermined relative positional relationship and it is aligned so that the laser may be emitted at an optically targeted angle, but is not limited thereto.

In addition, referring to FIG. 14, the detecting optic module 4220 may be arranged to be aligned with the above-described laser detecting module.

Herein, the detecting optic module 4220 being arranged to be aligned with the laser detecting module described above may mean that it is arranged to have a physically predetermined relative positional relationship and it is aligned so that the laser received at an optically targeted angle may be detected, but is not limited thereto.

In addition, FIG. 14 is a diagram illustrating an embodiment of the LiDAR device of FIG. 13, and the contents described herein referring to FIG. 13 are not restricted by the shape illustrated in FIG. 14.

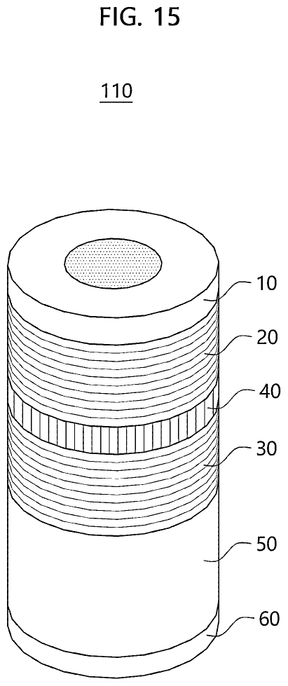

FIG. 15 is a diagram illustrating a laser emitting unit according to an embodiment.

Referring to FIG. 15, a laser emitting unit 100 according to an embodiment may include a VCSEL emitter 110.

The VCSEL emitter 110 according to an embodiment may include an upper metal contact 10, an upper DBR (Distributed Bragg reflector) layer 20, an active layer (quantum well) 30, a lower DBR (distributed Bragg reflector) layer 30, a substrate 50, and a lower metal contact 60.

In addition, the VCSEL emitter 110 according to an embodiment may emit a laser beam vertically from an upper surface. For example, the VCSEL emitter 110 may emit a laser beam in a direction perpendicular to a surface of an upper metal contact 10. In addition, for example, the VCSEL emitter 110 may emit a laser beam perpendicular to the active layer 40.

The VCSEL emitter 110 according to an embodiment may include an upper DBR layer 20 and a lower DBR layer 30.

The upper DBR layer 20 and the lower DBR layer 30 according to an embodiment may be formed of multiple reflective layers. For example, the multiple reflective layers may be arranged so that reflective layers with high reflectivity and reflective layers with low reflectivity are alternately arranged. Herein, the thickness of the multiple reflective layers may be one-fourth of the laser wavelength emitted from the VCSEL emitter 110, but is not limited thereto.

In addition, according to an embodiment, the upper DBR layer 20 and the lower DBR layer 30 may be doped with p-type and n-type. For example, the upper DBR layer 20 may be doped with p-type, and the lower DBR layer 30 may be doped with n-type. Alternatively, for example, the upper DBR layer 20 may be doped with n-type and the lower DBR layer 30 may be doped with p-type.

In addition, according to an embodiment, a substrate 50 may be placed between the lower DBR layer 30 and the lower metal contact 60. When the lower DBR layer 30 is doped with p-type, the substrate 50 may also be a p-type substrate, and when the lower DBR layer 30 is doped with n-type, the substrate 50 may also be an n-type substrate.

The VCSEL emitter 110 according to an embodiment may include an active layer 40.

The active layer 40 according to an embodiment may be placed between the upper DBR layer 20 and the lower DBR layer 30.

The active layer 40 according to an embodiment may include a plurality of quantum wells that generate a laser beam. The active layer 40 may emit a laser beam.

The VCSEL emitter 110 according to an embodiment may include a metal contact for electrical connection with a power source, etc. For example, the VCSEL emitter 110 may include an upper metal contact 10 and a lower metal contact 60.

In addition, the VCSEL emitter 110 according to an embodiment may be electrically connected to the upper DBR layer 20 and the lower DBR layer 30 through metal contacts.

For example, when the upper DBR layer 20 is doped with p-type and the lower DBR layer 30 is doped with n-type, the upper metal contact 10 may be supplied with a p-type power supply to electrically connect with the upper DBR layer 20, and the lower metal contact 60 may be supplied with a n-type power supply to electrically connect with the lower DBR layer 30.

In addition, for example, when the upper DBR layer 20 is doped with n-type and the lower DBR layer 30 is doped with p-type, the upper metal contact 10 may be supplied with n-type power supply to be electrically connected to the upper DBR layer 20, and the lower metal contact 60 may be supplied with p-type power supply to be electrically connected to the lower DBR layer 30.

The VCSEL emitter 110 according to an embodiment may include an oxidation area. The oxidation area may be arranged on top of the active layer.

The oxidation area according to an embodiment may be insulating. For example, electrical flow may be restricted in the oxidation area. For example, electrical connection may be restricted in the oxidation area.

In addition, the oxidation area according to an embodiment may act as an aperture. Specifically, since the oxidation area is insulating, a beam generated from the active layer 40 may be emitted only from a portion other than the oxidation area.

The laser emitting unit according to an embodiment may include a plurality of VCSEL emitters 110.

In addition, the laser emitting unit according to an embodiment may turn on the plurality of VCSEL emitters 110 at once or separately.

According to an embodiment, the laser emitting unit may emit laser beams having different wavelengths. For example, the laser emitting unit may emit a laser beam having a wavelength of 905 nm. In addition, for example, the laser emitting unit may emit a laser beam having a wavelength of 940 nm. In addition, for example, the laser emitting unit may emit a laser beam having a wavelength of 1550 nm.

In addition, according to an embodiment, the wavelength of the laser emitted from the laser emitting unit may change depending on the surrounding environment. For example, the wavelength of the laser emitted from the laser emitting unit may increase as the temperature of the surrounding environment increases. Alternatively, for example, the wavelength of the laser emitted from the laser emitting unit may decrease as the temperature of the surrounding environment decreases. The surrounding environment may include, but is not limited to, temperature, humidity, pressure, dust concentration, ambient light, altitude, gravity, acceleration, etc.

The laser emitting unit may emit a laser beam in a direction perpendicular to the support surface. Alternatively, the laser emitting unit may emit a laser beam in a direction perpendicular to the emission surface.

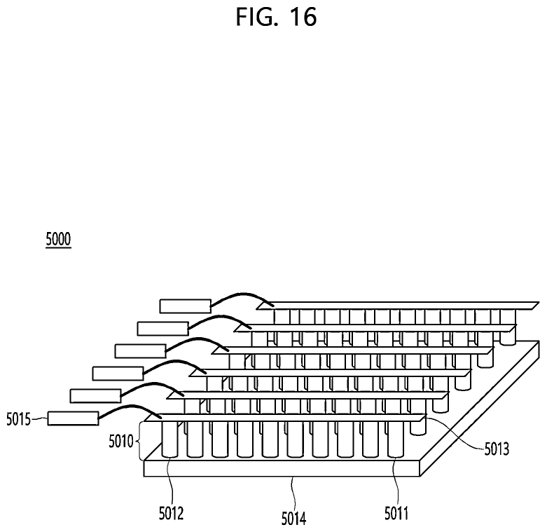

FIG. 16 is a diagram illustrating a laser emitting array according to an embodiment.

Referring to FIG. 16, a laser emitting array 5000 according to an embodiment may include a plurality of laser emitting units, at least one sub-array, at least one upper conductor, at least one lower conductor, and at least one power supply.

Herein, the at least one sub-array may refer to a group of laser emitting units that are operatively connected among the plurality of laser emitting units, a group of laser emitting units that are physically connected, a group of laser emitting units that are connected to the same power supply, a group of laser emitting units defined by at least one upper conductor, and a group of laser emitting units defined by a capacitor that is electrically connected to at least one power supply, but it is not limited thereto.

The at least one sub-array according to an embodiment may include a plurality of sub-arrays.

For example, at least one sub-array according to an embodiment may include, but is not limited to, a plurality of sub-arrays including a first sub-array 5010.

In addition, at least one sub-array according to an embodiment may include a plurality of laser emitting units.

For example, the first sub-array 5010 may include, but is not limited to, a plurality of laser emitting units.

In a more specific example, the first sub-array 5010 may include, but is not limited to, a first laser emitting unit 5011 and an Nth laser emitting unit 5012.

In addition, the plurality of laser emitting units included in the at least one sub-array according to an embodiment may be connected to at least one upper conductor.

For example, the plurality of laser emitting units included in the first sub-array 5010 according to an embodiment may be connected to the first upper conductor 5013 through an upper metal contact, but is not limited thereto.

In addition, for example, the first laser emitting unit 5011 and the Nth laser emitting unit 5012 included in the first sub-array 5010 according to an embodiment may be connected to the first upper conductor 5013 through each upper metal contact, but is not limited thereto.

In addition, the plurality of laser emitting units included in at least one sub-array according to an embodiment may be connected to at least one lower conductor.

For example, the plurality of laser emitting units included in at least one sub-array according to an embodiment may be connected to the first lower conductor 5014 through a lower metal contact, but is not limited thereto.

In addition, for example, the first laser emitting unit 5011 and the Nth laser emitting unit 5012 included in at least one sub-array according to an embodiment may be connected to the first lower conductor 5014 via a lower metal contact, but is not limited thereto.

In addition, the plurality of laser emitting units included in at least one sub-array according to an embodiment may receive energy from at least one power supply unit.

For example, the first laser emitting unit 5011 and the Nth laser emitting unit 5012 included in the first sub-array 5010 included in at least one sub-array according to an embodiment may be connected to a first power supply unit 5015 through the first upper conductor 5013 to receive energy from the first power supply unit 5015, but is not limited thereto.

In addition, for example, the first laser emitting unit 5011 and the Nth laser emitting unit 5012 included in the first sub-array 5010 included in at least one sub-array according to an embodiment may be connected to the first power supply unit 5015 through the first lower conductor 5014 to receive energy from the first power supply unit 5015, but is not limited thereto.

In addition, a plurality of laser emitting units included in at least one sub-array according to an embodiment may receive voltage from at least one power supply.

For example, the first laser emitting unit 5011 and the Nth laser emitting unit 5012 included in the first sub-array 5010 included in at least one sub-array according to an embodiment may be connected to the first power supply unit 5015 through the first upper conductor 5013 to receive voltage from the first power supply unit 5015, but is not limited thereto.

In addition, for example, the first laser emitting unit 5011 and the Nth laser emitting unit 5012 included in the first sub-array 5010 included in at least one sub-array according to an embodiment may be connected to the first power supply unit 5015 through the first lower conductor 5014 to receive voltage from the first power supply unit 5015, but is not limited thereto.

In addition, the length of the electrical paths between at least one power supply unit and at least one laser emitting unit included in at least one sub-array according to an embodiment may be different from each other.

For example, as shown in FIG. 16, the electrical path between the first laser emitting unit 5011 included in the first sub-array 5010 and the first power supply unit 5015 may be longer than the electrical path between the Nth laser emitting unit 5012 and the first power supply unit 5015, but is not limited thereto.

Herein, the electrical path may refer to a path through which current or electrons move from the power supply unit to each laser emitting unit, and may include a concept that may be understood as an electrical path by a person skilled in the art.

In addition, since the above-described contents of the first sub-array 5010 and the like may be applied to other sub-arrays and the like, redundant descriptions will be omitted.

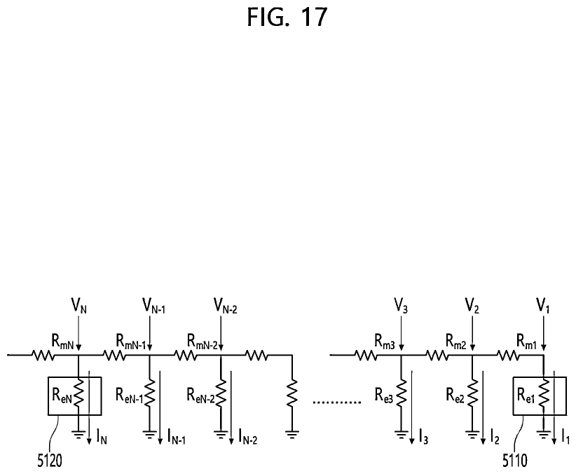

FIG. 17 is a diagram simply expressing a circuit diagram of a laser emitting array according to an embodiment.

More specifically, FIG. 17 is a circuit diagram simply illustrating an electrical circuit of the first sub-array included in the laser emitting array described through FIG. 16.

FIG. 17 shows a circuit structure that is connected to a power supply unit through the upper conductor and is connected to the ground through the lower conductor, for convenience of explanation, as shown in FIG. 16, in which R_m indicates the resistance formed by the above-described upper conductor and the like, and R_e indicates the resistance of the above-described laser emitting units, and.

According to an embodiment, the voltages applied to each of the plurality of laser emitting units included in the first sub-array may be different from each other.

For example, according to an embodiment, the voltage applied to the Nth laser emitting unit 5120 may be the Nth voltage V_N; the voltage applied to the N-1th laser emitting unit may be the N-1th voltage V_N-1 dropped from the Nth voltage V_N by the resistance R_mN-1 of the conductor; the voltage applied to the N-2th laser emitting unit may be the N-2nd voltage V_N-2 dropped from the N-1st voltage V_N-1 by the resistance R_mN-2 of the conductor; the voltage applied by the first laser emitting unit 5110 may be the first voltage V1 dropped from the Nth voltage V_N by the resistances R_m1 to R_mN-1 of the conductor.

In addition, according to an embodiment, the magnitudes of the current passing through each of the plurality of laser emitting units included in the first sub-array may be different from each other.

For example, according to an embodiment, the Nth current I_N which is the magnitude of the current passing through the Nth laser emitting unit 5120 may be determined by the Nth voltage V_N and the resistance R_eN of the Nth laser emitting unit 5120, and the first current I_1 which is the magnitude of the current passing through the first laser emitting unit 5110 may be determined by the first voltage V_1 and the resistance R_1 of the first laser emitting unit 5110, in which the first current I_1 and the Nth current I_N may be different from each other.

According to an embodiment, the power of the laser emitted from the plurality of laser emitting units included in the first sub-array may be related to the magnitude of the voltage applied to each of the plurality of laser emitting units or the magnitude of the current passing through the plurality of laser emitting units.

For example, the power of the laser emitted from the first laser emitting unit 5110 may be related to the first current I_1 which is the magnitude of the current passing through the first laser emitting unit 5110, and the power of the laser emitted from the Nth laser emitting unit 5120 may be related to the Nth current I_N which is the magnitude of the current passing through the Nth laser emitting unit 5120.

In addition, for example, the power of the laser emitted from the first laser emitting unit 5110 may be related to the first voltage V_1 which is the magnitude of the voltage applied to the first laser emitting unit 5110, and the power of the laser emitted from the Nth laser emitting unit 5120 may be related to the Nth voltage V_N which is the magnitude of the voltage applied to the Nth laser emitting unit 5120.

According to an embodiment, the power of the laser emitted from the plurality of laser emitting units included in the first sub-array may be greater as the magnitude of the voltage applied to each of the plurality of laser emitting units is greater or the magnitude of the current passing through the plurality of laser emitting units is greater.

For example, when the Nth voltage V_N which is the magnitude of the voltage applied to the Nth laser emitting unit 5120 is greater than the first voltage V_1 which is the magnitude of the voltage applied to the first laser emitting unit 5110, the power of the laser emitted from the Nth laser emitting unit 5120 may be greater than the power of the laser emitted from the first laser emitting unit 5110.

In addition, for example, when the Nth current V_N which is the size of the current passing through the Nth laser emitting unit 5120 is greater than the first current V_1 which is the size of the current passing through the first laser emitting unit 5110, the power of the laser emitted from the Nth laser emitting unit 5120 may be greater than the power of the laser emitted from the first laser emitting unit 5110.

As a result, when the resistances of the first to Nth laser emitting units 5110 to 5120 are all the same, the power of the lasers emitted from the first to Nth laser emitting units 5110 to 5120 may be different from each other, which results that at least one conductor is used to form an electrical path between each laser emitting unit from the power supply unit, due to the difference in the resistance of the conductor and the electrical path.

However, in the case of the LiDAR device, in order to improve the accuracy of distance measurement and secure the performance of the LiDAR device, it is necessary to secure the uniformity of the amount of light received by each detecting unit included in the laser detecting array under the same conditions.

Therefore, in the case of the laser emitting array used in the LiDAR device, it is necessary to secure the uniformity between the laser emitting powers.

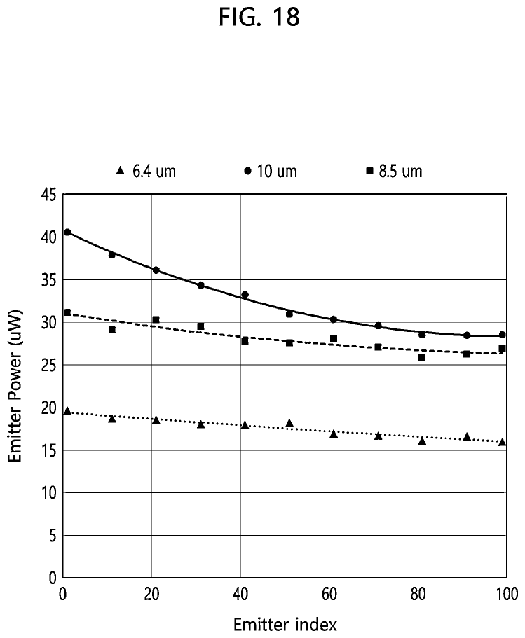

FIG. 18 is a diagram illustrating the powers of lasers emitted from a plurality of laser emitting units included in a laser emitting array according to an embodiment.

More specifically, FIG. 18 is a graph illustrating a first sub-array included in a laser emitting array according to an embodiment, in which an X-axis indicates the index of the laser emitting units included in the first sub-array, and a Y-axis indicates the power of the laser emitted from each laser emitting unit.

Herein, the index of the laser emitting units included in the first sub-array may be numbered in ascending order starting from the shortest electrical path from the power supply unit to each laser emitting unit.

For example, when the number of laser emitting units included in the first sub-array is 100, and the length of the electrical path from the power supply unit to the first laser emitting unit is the shortest, and the length of the electrical path from the power supply unit to the second laser emitting unit is the longest, the index of the first laser emitting unit may be expressed as 1, and the index of the second laser emitting unit may be expressed as 100, but is not limited thereto.

In addition, for example, in the case of the laser emitting array described through FIG. 17, the index of the Nth laser emitting unit 5120 may be indicated as 1, and the index of the first laser emitting unit 5110 may be indicated as 100, but is not limited thereto.

In addition, referring to FIG. 18, the distribution of the power of the laser emitted from each of the laser emitting units may be known according to the diameter of the laser emitting units included in the first sub-array according to an embodiment. Hereinafter, a more specific description will be given using exemplary figures.

According to an embodiment, when the diameter of the plurality of laser emitting units included in the first sub-array is designed to be 6.4 um, the power of the laser emitted from the laser emitting unit corresponding to the index “1” may be 19.6 uW, and the power of the laser emitted from the laser emitting unit corresponding to the index “99” may be 16 uW.

Herein, the power of the laser emitted from the laser emitting unit corresponding to the index “99” may be about 82% of the power of the laser emitted from the laser emitting unit corresponding to the index “1”.

In addition, according to an embodiment, when the diameters of the plurality of laser emitting units included in the first sub-array are designed to be 8.5 um, the power of the laser emitted from the laser emitting unit corresponding to the index “1” may be 31.2 uW, and the power of the laser emitted from the laser emitting unit corresponding to the index “99” may be 25.8 uW.

Herein, the power of the laser emitted from the laser emitting unit corresponding to the index “99” may be about 80% of the power of the laser emitted from the laser emitting unit corresponding to the index “1”.

In addition, according to an embodiment, when the diameters of the plurality of laser emitting units included in the first sub-array are designed to be 10 um, the power of the laser emitted from the laser emitting unit corresponding to the index “1” may be 40.66 uW, and the power of the laser emitted from the laser emitting unit corresponding to the index “99” may be 28.6 uW.

Herein, the power of the laser emitted from the laser emitting unit corresponding to the index “99” may be about 70% of the power of the laser emitted from the laser emitting unit corresponding to the index “1”.

Referring again to FIG. 18, results may be summarized as follows.

For example, in the case of the laser emitting array according to an embodiment, the longer the length of the electrical path from the power supply unit to the corresponding laser emitting unit (the larger the index number), the more the power of the emitted laser may decrease.

In addition, for example, in the case of the laser emitting array according to an embodiment, as the diameters of the laser emitting units constituting the laser emitting array decrease, the difference in the power of the emitted laser between the laser emitting units constituting the laser emitting array may decrease.

In addition, for example, in the case of a laser emitting array according to an embodiment, as the diameter of the laser emitting units constituting the laser emitting array increase, the overall power of the lasers emitted from the laser emitting units constituting the laser emitting array may increase.

Therefore, when configuring the laser emitting array according to an embodiment, although the diameter of each laser emitting unit is required to be increased to improve the power of the laser emitted from each laser emitting unit, the uniformity of the power of the laser emitted from the laser emitting array may decrease when the diameters of the laser emitting units constituting the laser emitting array increase.

As a result, it may be necessary to design the laser emitting array for improving the overall uniformity while improving the power of each laser emitted from the laser emitting array.

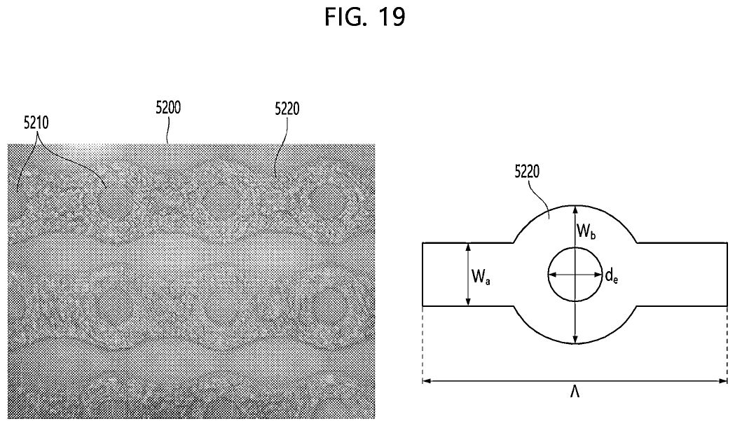

FIG. 19 is a diagram illustrating an image of a laser emitting array and a method for obtaining the resistance of the upper conductor included in the laser emitting array, according to an embodiment.

Referring to FIG. 19, a laser emitting array 5200 according to an embodiment may include a plurality of laser emitting units, and each of the plurality of laser emitting units may include an aperture 5210 for emitting lasers.

Herein, the aperture 5210 may refer to a portion for allowing light generated inside each of the plurality of laser emitting units to be outputted to the outside, but is not limited thereto.

In addition, since the above-described contents may be applied to the plurality of laser emitting units, redundant descriptions will be omitted.

In addition, the laser emitting array 5200 according to an embodiment may include an upper conductor 5220 electrically connected to upper contacts included in the plurality of laser emitting units.

In this case, since the above-described contents may be applied to the upper conductor 5220, redundant descriptions will be omitted.

In addition, according to an embodiment, the resistance of a specific region of the upper conductor 5220 may be obtained by the following equation.

Rm=ρx((Λ−w_b)/(txw_a)+(TT(w_b+d_e)/4)/(tx(w_b×d_e)) Equation

Wherein ρ indicate resistivity, which may indicate a unique property of an object constituting the upper conductor 5220, A may indicate a length of a specific region, w_b may indicate a diameter of the outer surface of the upper conductor 5220 with respect to the center of the aperture of the laser emitting unit included in a specific region, t may indicate a height of the upper conductor 5220, w_a may indicate a width of the upper conductor 5220 in an area included in a specific region but where the laser emitting unit is not located, d_e may indicate a diameter of the aperture of the laser emitting unit included in a specific region, but is not limited thereto.

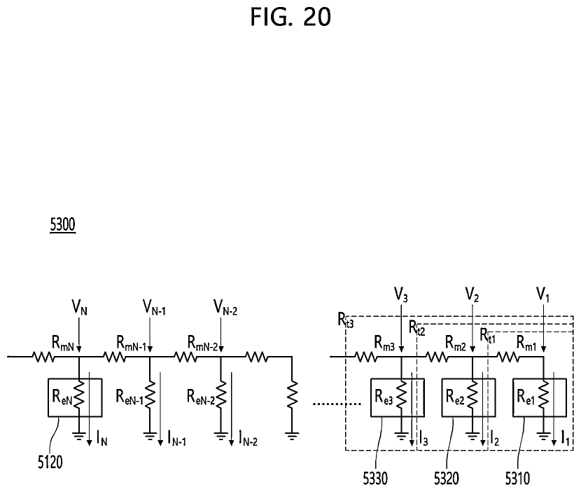

FIG. 20 is a circuit diagram illustrating an exemplary electrical circuit of a laser emitting array according to an embodiment.

Referring to FIG. 20, a laser emitting array 5300 according to an embodiment may include a first sub-array, and the first sub-array may include a plurality of laser emitting units.

For example, a first sub-array according to an embodiment may include a first laser emitting unit 5310, a second laser emitting unit 5320, a third laser emitting unit 5330, and an Nth laser emitting unit 5340, but is not limited thereto.

In addition, in order to design a laser emitting array according to an embodiment, the size of the current passing through each laser emitting unit included in the first sub-array may be calculated.

For example, when the size of the current passing through the first laser emitting unit 5310 is the first current I_1 and the size of the current passing through the second laser emitting unit 5320 is the second current I_2, the size of the resistance R_e2 corresponding to the second laser emitting unit 5320 may be designed to be the same as that of the combined resistance R_t1 of the resistance R_e1 corresponding to the first laser emitting unit 5310 and the resistance R_m1 of the first upper conductor, in order to cause the sizes of the first current I_1 and the second current I_2 to be equal to each other.

In addition, for example, when the size of the current passing through the first laser emitting unit 5310 is the first current I_1, the size of the current passing through the second laser emitting unit 5320 is the second current I_2, and the size of the current passing through the third laser emitting unit 5330 is the third current I_3, the size of the resistance R_e3 corresponding to the third laser emitting unit 5330 may be designed to be equal to that of the combined resistance R_t2 of the resistance R_e1 corresponding to the first laser emitting unit 5310, the resistance R_m1 of the first upper conductor, the resistance R_e2 corresponding to the second laser emitting unit 5320, and the resistance R_m2 of the second upper conductor, in order to cause the sizes of the currents passing through the first to third currents I_1 to I_3 to be equal to each other.

When the calculation is performed as described above with the example, the relationship between the first to Nth laser emitting units 5310 to 5340 may be derived, and the first to Nth laser emitting units 5310 to 5340 may be designed based on the same. Since any overlapping content with the above-described contents may be sufficiently explained based the above-described contents, redundant description will be omitted.

In addition, according to an embodiment, the voltages applied to each of the first to Nth laser emitting units 5310 to 5340 included in the first sub-array may be different from each other.

For example, according to an embodiment, the voltage applied to the Nth laser emitting unit may be the Nth voltage V_N, the voltage applied to the N-1th laser emitting unit may be the N-1th voltage V_N-1 dropped from the Nth voltage V_N by the resistance R_mN-1 of the conductor, the voltage applied to the N-2th laser emitting unit may be the N-2nd voltage V_N-2 dropped from the N-1st voltage V_N-1 by the resistance R_mN-2 of the conductor, the voltage applied by the first laser emitting unit may be the first voltage V1 dropped from the Nth voltage V_N by the resistance R_m1 to R_mN-1 of the conductor.

Herein, since the resistance sizes of the first to Nth laser emitting units 5310 to 5340 included in the first sub-array are different from each other as described above, although the voltages applied to the first to Nth laser emitting units 5310 to 5340 are different from each other, the size of the current passing through the first to Nth laser emitting units 5310 to 5340 may be equal to each other. Herein, the size of the power of the laser emitted from the first to Nth laser emitting units 5310 to 5340 included in the first sub-array may be equal to each other.

In addition, according to an embodiment, the resistance of the first to Nth laser emitting units 5310 to 5340 may be associated with the size of the first to Nth laser emitting units 5310 to 5340)

For example, according to an embodiment, the resistance of the first to Nth laser emitting units 5310 to 5340 may be inversely proportional to the size of the first to Nth laser emitting units 5310 to 5340, but is not limited thereto.

In addition, for example, according to an embodiment, the resistance of the first to Nth laser emitting units 5310 to 5340 may be inversely proportional to the diameter of the first to Nth laser emitting units 5310 to 5340, but is not limited thereto.

In addition, according to an embodiment, the resistance of the first to Nth laser emitting units 5310 to 5340 may be designed to increase from the first laser emitting unit 5310 to the Nth laser emitting unit 5340.

In addition, according to an embodiment, the resistance of the first to Nth laser emitting units 5310 to 5340 may be designed to gradually increase from the first laser emitting unit 5310 to the Nth laser emitting unit 5340, but is not limited thereto.

In addition, for example, according to an embodiment, the resistance of the first to Nth laser emitting units 5310 to 5340 may be designed to stepwise increase from the first laser emitting unit 5310 to the Nth laser emitting unit 5340, but is not limited thereto.

In addition, according to an embodiment, the size of the first to Nth laser emitting units 5310 to 5340 may be designed to decrease from the first laser emitting unit 5310 to the Nth laser emitting unit 5340.

For example, according to an embodiment, the size of the first to Nth laser emitting units 5310 to 5340 may be designed to gradually decrease from the first laser emitting unit 5310 to the Nth laser emitting unit 5340, but is not limited thereto.

In addition, for example, according to an embodiment, the size of the first to Nth laser emitting units 5310 to 5340 may be designed to stepwise decrease from the first laser emitting unit 5310 to the Nth laser emitting unit 5340, but is not limited thereto.

In addition, according to an embodiment, the diameter of the first to Nth laser emitting units 5310 to 5340 may be designed to decrease from the first laser emitting unit 5310 to the Nth laser emitting unit 5340.

For example, according to an embodiment, the diameter of the first to Nth laser emitting units 5310 to 5340 may be designed to gradually decrease from the first laser emitting unit 5310 to the Nth laser emitting unit 5340, but is not limited thereto.

In addition, for example, according to an embodiment, the diameter of the first to Nth laser emitting units 5310 to 5340 may be designed to stepwise decrease from the first laser emitting unit 5310 to the Nth laser emitting unit 5340, but is not limited thereto.

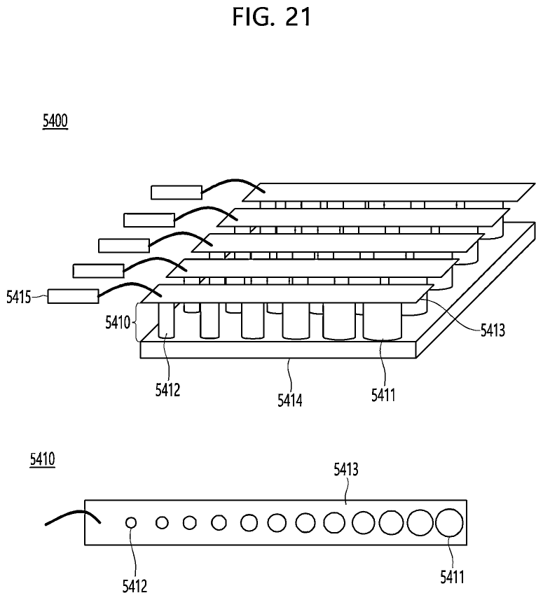

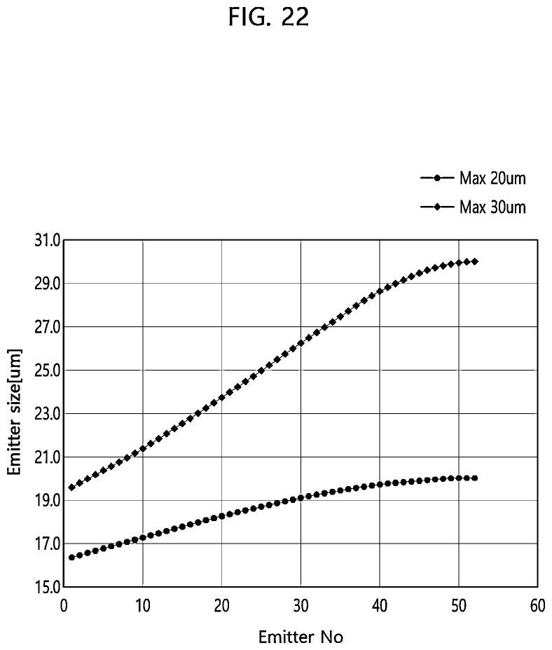

FIG. 21 and FIG. 22 are diagrams illustrating a laser emitting array according to an embodiment.

Referring to FIG. 21, a laser emitting array 5400 according to an embodiment may include a plurality of laser emitting units, at least one sub-array, at least one upper conductor, at least one lower conductor, and at least one power supply.

In particular, FIG. 21 illustrates the laser emitting array 5400 according to an embodiment, a first sub-array 5410 included in the laser emitting array 5400, a first power supply 5415, a first upper conductor 5413, a first lower conductor 5414, a first laser emitting unit 5411 included in the first sub-array 5410, and an Nth laser emitting unit 5412. Since the above-described contents may be applied to these configurations, redundant descriptions will be omitted.

Referring back to FIG. 21, the laser emitting array 5400 according to an embodiment may be designed such that the longer the length of the electrical path from the power supply unit to the laser emitting unit the greater the size of the laser emitting unit.

For example, according to an embodiment, when the length of the electrical path from the first power supply unit 5415 to the first laser emitting unit 5411 included in the first sub-array 5410 is longer than the length of the electrical path to the Nth laser emitting unit 5412 included in the first sub-array 5410, the size of the first laser emitting unit 5411 may be designed to be larger than the size of the Nth laser emitting unit 5412.

In addition, for example, according to an embodiment, when the length of the electrical path from the first power supply unit 5415 to the first laser emitting unit 5411 included in the first sub-array 5410 is longer than the length of the electrical path to the Nth laser emitting unit 5412 included in the first sub-array 5410, the diameter of the first laser emitting unit 5411 may be designed to be larger than the diameter of the Nth laser emitting unit 5412.

In addition, referring to FIG. 21, the laser emitting array 5400 according to an embodiment may be designed so that the longer the length of the electrical path from the power supply unit to the laser emitting unit, the lager the size of the aperture included in the laser emitting unit.

For example, according to an embodiment, when the length of the electrical path from the first power supply unit 5415 to the first laser emitting unit 5411 included in the first sub-array 5410 is longer than the length of the electrical path to the Nth laser emitting unit 5412 included in the first sub-array 5410, the size of the aperture included in the first laser emitting unit 5411 may be designed to be larger than the size of the aperture included in the Nth laser emitting unit 5412.

In addition, referring to FIG. 21, the laser emitting array 5400 according to an embodiment may be designed so that the longer the length of the electrical path from the power supply unit to the laser emitting unit, the smaller the resistance of the laser emitting unit.

For example, according to an embodiment, when the length of the electrical path from the first power supply unit 5415 to the first laser emitting unit 5411 included in the first sub-array 5410 is longer than the length of the electrical path to the Nth laser emitting unit 5412 included in the first sub-array 5410, the resistance of the first laser emitting unit 5411 may be designed to be smaller than the resistance of the Nth laser emitting unit 5412.

In addition, referring to FIG. 21, the laser emitting array 5400 according to an embodiment may be designed so that the longer the length of the electrical path from the power supply unit to the laser emitting unit, the smaller the magnitude of the voltage applied to the laser emitting unit.

For example, according to an embodiment, when the length of the electrical path from the first power supply unit 5415 to the first laser emitting unit 5411 included in the first sub-array 5410 is longer than the length of the electrical path to the Nth laser emitting unit 5412 included in the first sub-array 5410, the magnitude of the voltage applied to the first laser emitting unit 5411 may be designed to be smaller than the magnitude of the voltage applied to the Nth laser emitting unit 5412.

In addition, FIG. 22 illustrates the sizes of laser emitting units included in the laser emitting array designed according to the design methods described above.

Herein, FIG. 22 illustrates the case where the size of the first laser emitting unit 5411 described above is designed to be 20 um and the case where it is designed to be 30 um, in which it is noted that the first laser emitting unit 5411 described above is matched to Emitter No. 52, and the Nth laser emitting unit 5412 described above is matched to Emitter No. 1, for the convenience of understanding in the figure.

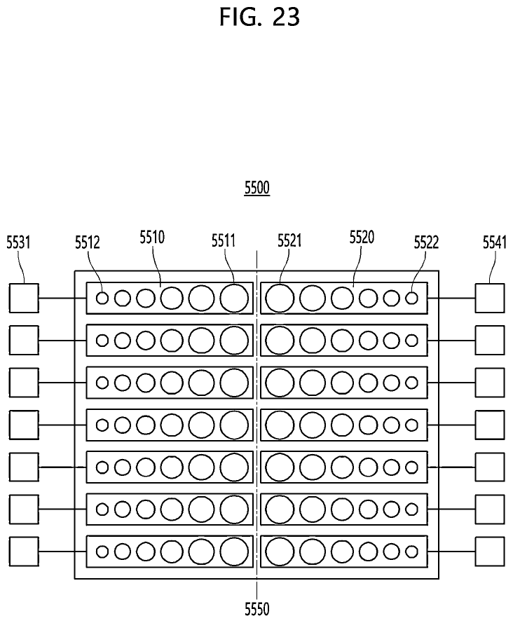

FIG. 23 is a diagram illustrating a laser emitting array according to an embodiment.

Referring to FIG. 23, a laser emitting array 5500 according to an embodiment may include a plurality of laser emitting units, a plurality of sub-arrays, and a plurality of power supply units.

Herein, each of the plurality of sub-arrays may refer to a group of laser emitting units that are operatively connected among the plurality of laser emitting units, may refer to a group of laser emitting units that are physically connected, may refer to a group of laser emitting units that are connected to the same power supply unit, may refer to a group of laser emitting units defined by at least one upper conductor, and may refer to a group of laser emitting units defined by a capacitor that is electrically connected to at least one power supply unit, but is not limited thereto.

Referring again to FIG. 23, the laser emitting array 5500 according to an embodiment may include a plurality of sub-arrays.

For example, a laser emitting array 5500 according to an embodiment may include, but is not limited to, a first sub-array 5510 and a second sub-array 5520.

In addition, the laser emitting array 5500 according to an embodiment may include a plurality of power supply units.

For example, the laser emitting array 5500 according to an embodiment may include a first power supply unit 5531 for supplying energy to the first sub-array 5510 and a second power supply unit 5541 for supplying energy to the second sub-array 5520, but is not limited thereto.

In addition, the laser emitting array 5500 according to an embodiment may include a plurality of laser emitting units.

For example, a laser emitting array 5500 according to an embodiment may include the first sub-array 5510 and the second sub-array 5520, in which the first sub-array 5510 may include a first laser emitting unit 5511 and a second laser emitting unit 5512, and the second sub-array 5520 may include a third laser emitting unit 5521 and a fourth laser emitting unit 5522, but is not limited thereto.

However, since the above-described contents may be applied to the laser emitting array 5500, the first sub-array 5510, the second sub-array 5520, the first laser emitting unit 5511, the second laser emitting unit 5512, the third laser emitting unit 5521, the fourth laser emitting unit 5522, the first power supply unit 5531, and the second power supply unit 5541 according to an embodiment, redundant descriptions will be omitted.

Referring again to FIG. 23, the laser emitting array 5500 according to an embodiment may be designed such that the size of the laser emitting unit increases as the length of the electrical path from the power supply unit to the laser emitting unit becomes longer.

For example, according to an embodiment, the first laser emitting unit 5511 included in the first sub-array 5510 may be arranged such that the length of the electrical path from the first power supply unit 5531 is longer than that of the second laser emitting unit 5512 included in the first sub-array 5510, in which the size of the first laser emitting unit 5511 may be designed to be larger than that of the second laser emitting unit 5512, but is not limited thereto.

IN addition, for example, according to an embodiment, the first laser emitting unit 5511 included in the first sub-array 5510 may be arranged so that the length of the electrical path from the first power supply unit 5531 is longer than that of the second laser emitting unit 5512 included in the first sub-array 5510, in which the diameter of the first laser emitting unit 5511 may be designed to be larger than that of the second laser emitting unit 5512, but is not limited thereto.

In addition, for example, according to an embodiment, the third laser emitting unit 5521 included in the second sub-array 5520 may be arranged so that the length of the electrical path from the second power supply unit 5541 is longer than that of the fourth laser emitting unit 5522 included in the second sub-array 5520, in which the size of the third laser emitting unit 5521 may be designed to be larger than that of the fourth laser emitting unit 5522, but is not limited thereto.

In addition, for example, according to an embodiment, the third laser emitting unit 5521 included in the second sub-array 5520 may be arranged so that the length of the electrical path from the second power supply unit 5541 is longer than that of the fourth laser emitting unit 5522 included in the second sub-array 5520, in which the diameter of the third laser emitting unit 5521 may be designed to be larger than that of the fourth laser emitting unit 5522, but is not limited thereto.

In addition, according to an embodiment, the laser emitting array 5500 may be designed so that as it gets closer to the horizontal center of the laser emitting array 5500, the length of the electrical path from the power supply unit to the laser emitting unit becomes longer.

For example, in the case of the first sub-array 5510 included in the laser emitting array 5500 according to an embodiment, the first laser emitting unit 5511 may be disposed closer to the horizontal center 5550 of the laser emitting array 5500 than the second laser emitting unit 5512, in which the length of the electrical path from the first power supply unit 5531 to the first laser emitting unit 5511 may be designed to be longer than the length of the electrical path from the first power supply unit 5531 to the second laser emitting unit 5512, but is not limited thereto.

In addition, for example, in the case of the second sub-array 5520 included in the laser emitting array 5500 according to an embodiment, the third laser emitting unit 5521 may be disposed closer to the horizontal center 5550 of the laser emitting array 5500 than the fourth laser emitting unit 5522, in which the length of the electrical path from the second power supply unit 5541 to the third laser emitting unit 5521 may be designed to be longer than the length of the electrical path from the second power supply unit 5541 to the fourth laser emitting unit 5522, but is not limited thereto.

In addition, the laser emitting array 5500 according to an embodiment may be designed to have a larger size of the laser emitting unit as it gets closer to the horizontal center of the laser emitting array 5500.

For example, in the case of the first sub-array 5510 included in the laser emitting array 5500 according to an embodiment, the first laser emitting unit 5511 may be disposed closer to the horizontal center 5550 of the laser emitting array 5500 than the second laser emitting unit 5512, in which the size of the first laser emitting unit 5511 may be designed to be larger than the size of the second laser emitting unit 5512, but is not limited thereto.

In addition, for example, in the case of the first sub-array 5510 included in the laser emitting array 5500 according to an embodiment, the first laser emitting unit 5511 may be disposed closer to the horizontal center 5550 of the laser emitting array 5500 than the second laser emitting unit 5512, in which the diameter of the first laser emitting unit 5511 may be designed to be larger than that of the second laser emitting unit 5512, but is not limited thereto.

In addition, for example, in the case of the second sub-array 5520 included in the laser emitting array 5500 according to an embodiment, the third laser emitting unit 5521 may be disposed closer to the horizontal center 5550 of the laser emitting array 5500 than the fourth laser emitting unit 5522, in which the size of the third laser emitting unit 5521 may be designed to be larger than that of the fourth laser emitting unit 5522, but is not limited thereto.

In addition, for example, in the case of the second sub-array 5520 included in the laser emitting array 5500 according to an embodiment, the third laser emitting unit 5521 may be disposed closer to the horizontal center 5550 of the laser emitting array 5500 than the fourth laser emitting unit 5522, in which the diameter of the third laser emitting unit 5521 may be designed to be larger than the diameter of the fourth laser emitting unit 5522, but is not limited thereto.

In addition, the laser emitting array 5500 according to an embodiment may be designed so that the resistance of the laser emitting unit decreases as it gets closer to the horizontal center of the laser emitting array 5500.

For example, in the case of the first sub-array 5510 included in the laser emitting array 5500 according to an embodiment, the first laser emitting unit 5511 may be disposed closer to the horizontal center 5550 of the laser emitting array 5500 than the second laser emitting unit 5512, in which the resistance of the first laser emitting unit 5511 may be designed to be smaller than that of the second laser emitting unit 5512, but is not limited thereto.

In addition, for example, in the case of the second sub-array 5520 included in the laser emitting array 5500 according to an embodiment, the third laser emitting unit 5521 may be disposed closer to the horizontal center 5550 of the laser emitting array 5500 than the fourth laser emitting unit 5522, in which the resistance of the third laser emitting unit 5521 may be designed to be smaller than that of the fourth laser emitting unit 5522, but is not limited thereto.

In addition, according to an embodiment, the first power supply unit 5531 and the second power supply unit 5541 may supply energy to the first sub-array 5510 and the second sub-array 5520 at the same timing, respectively.

For example, when a common drive switch is provided for controlling operations of the first sub-array 5510 and the second sub-array 5520, capacitors included in each of the first power supply unit 5531 and the second power supply unit 5541 may be charged before the common drive switch is operated, so that when the common drive switch is operated, energy may be supplied to the first sub-array 5510 and the second sub-array 5520 at the same timing, but this is not limited thereto.

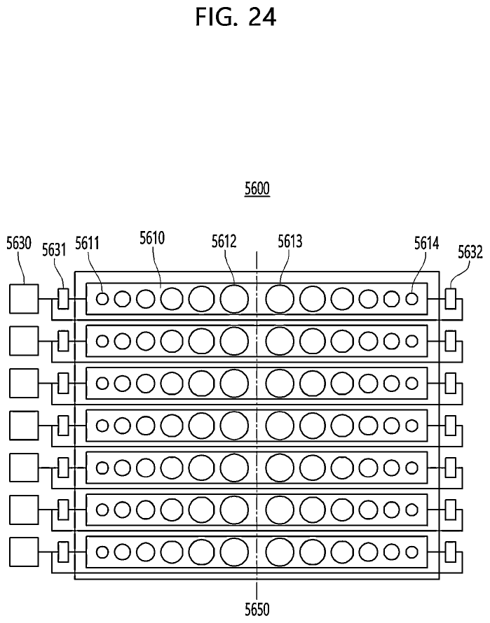

FIG. 24 is a diagram illustrating a laser emitting array according to an embodiment.

Referring to FIG. 24, a laser emitting array 5600 according to an embodiment may include a plurality of laser emitting units, at least one sub-array, and at least one power supply unit.

Herein, the at least one sub-array may refer to a group of laser emitting units that are operatively connected among the plurality of laser emitting units, may refer to a group of laser emitting units that are physically connected, may refer to a group of laser emitting units that are connected to the same power supply, may refer to a group of laser emitting units defined by the at least one upper conductor, and may refer to a group of laser emitting units defined by a capacitor that is electrically connected to the at least one power supply, but is not limited thereto.

Referring again to FIG. 23, the laser emitting array 5600 according to an embodiment may include at least one sub-array.

For example, the laser emitting array 5600 according to an embodiment may include a first sub-array 5610, but is not limited thereto.

In addition, the laser emitting array 5600 according to an embodiment may include at least one power supply unit.

For example, the laser emitting array 5600 according to an embodiment may include, but is not limited to, a first power supply unit 5630 for supplying energy to the first sub-array 5610.

In addition, the laser emitting array 5500 according to an embodiment may include a plurality of laser emitting units.

For example, the laser emitting array 5600 according to an embodiment may include the first sub-array 5610, and the first sub-array 4610 may include, but is not limited to, a first laser emitting unit 5611, a second laser emitting unit 5612, a third laser emitting unit 5613, and a fourth laser emitting unit 5614.

However, since the above-described contents may be applied to the laser emitting array 5600, the first sub-array 5610, the first laser emitting unit 5611, the second laser emitting unit 5612, the third laser emitting unit 5613, the fourth laser emitting unit 5614, and the first power supply unit 5630 according to an embodiment, redundant descriptions will be omitted.

Referring again to FIG. 24, the laser emitting array 5600 according to an embodiment may include at least one contact positioned between the power supply unit and the laser emitting unit.

For example, a laser emitting array 5600 according to an embodiment may include, but is not limited to, a first contact 5631 and a second contact 5632 positioned between the first power supply 5630 and the first sub-array 5610.

Herein, according to an embodiment, the first contact 5631 may be positioned on one side of the laser emitting array 5600, and the second contact 5632 may be positioned on the other side of the laser emitting array 5600.

For example, according to an embodiment, the first contact 5631 may be located on the left side of the first sub-array 5610 included in the laser emitting array 5600, and the second contact 5632 may be located on the right side of the first sub-array 5610 included in the laser emitting array 5600, but is not limited thereto.

In addition, according to an embodiment, the laser emitting array 5600 may be designed such that the size of the laser emitting units is determined according to the length of the electrical path from the contacts associated with the sub-array to the laser emitting unit.

For example, according to an embodiment, when the first laser emitting unit 5611 and the second laser emitting unit 5612 included in the first sub-array 5610 are arranged so that the length of the electrical path from the first contact 5631 is shorter than that of the electrical path from the second contact 5632, and the length of the electrical path from the first contact 5631 in the second laser emitting unit 5612 is arranged to be longer than that in the first laser emitting unit 5611, the size of the second laser emitting unit 5612 may be designed to be larger than that of the first laser emitting unit 5611, but is not limited thereto.

In addition, for example, according to an embodiment, when the third laser emitting unit 5613 and the fourth laser emitting unit 5614 included in the first sub-array 5610 are laser emitting units arranged so that the length of the electrical path from the second contact 5632 is shorter than the length of the electrical path from the first contact 5631, and the length of the electrical path from the second contact 5632 in the third laser emitting unit 5613 is arranged to be longer than that in the fourth laser emitting unit 5614, the size of the third laser emitting unit 5613 may be designed to be larger than the size of the fourth laser emitting unit 5614, but is not limited thereto.

In addition, the laser emitting array 5600 according to an embodiment may be designed such that as it gets closer to the horizontal center of the laser emitting array 5600, the size of the laser emitting unit increases.

For example, in the case of the first sub-array 5610 included in the laser emitting array 5600 according to an embodiment, the second laser emitting unit 5612 may be disposed closer to the horizontal center 5650 of the laser emitting array 5600 than the first laser emitting unit 5611, in which the size of the second laser emitting unit 5612 may be designed to be larger than that of the first laser emitting unit 5611, but is not limited thereto.

In addition, for example, in the case of the first sub-array 5610 included in the laser emitting array 5600 according to an embodiment, the third laser emitting unit 5613 may be disposed closer to the horizontal center 5650 of the laser emitting array 5600 than the fourth laser emitting unit 5614, in which the size of the third laser emitting unit 5613 may be designed to be larger than the size of the fourth laser emitting unit 5614, but is not limited thereto.

In addition, the laser emitting array 5600 according to an embodiment may be designed so that as it gets closer to the horizontal center of the laser emitting array 5600, the resistance of the laser emitting unit decreases.

For example, in the case of the first sub-array 5610 included in the laser emitting array 5600 according to an embodiment, the second laser emitting unit 5612 may be disposed closer to the horizontal center 5650 of the laser emitting array 5600 than the first laser emitting unit 5611, in which the resistance of the second laser emitting unit 5612 may be designed to be smaller than that of the first laser emitting unit 5611, but is not limited thereto.

In addition, for example, in the case of the first sub-array 5610 included in the laser emitting array 5600 according to an embodiment, the third laser emitting unit 5613 may be disposed closer to the horizontal center 5650 of the laser emitting array 5600 than the fourth laser emitting unit 5614, in which the resistance of the third laser emitting unit 5613 may be designed to be smaller than that of the fourth laser emitting unit 5614, but is not limited thereto.

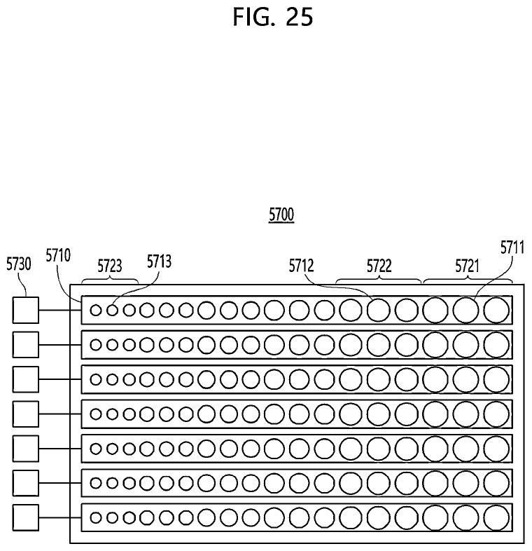

FIG. 25 is a diagram illustrating a laser emitting array according to an embodiment.

Before explaining FIG. 25, as described through FIGS. 16 to 24, the length of the electrical path from the power supply, the resistance of the upper conductor, and the like may be considered in order to make the power of the lasers emitted from the laser emitting array more uniform.

Therefore, when the length of the electrical path from the power supply to each laser emitting unit is different from each other, since the magnitudes of the voltage applied to each laser emitting unit are different from each other, the size of each laser emitting unit may need to be different from each other in order to make the power of the lasers emitted from each laser emitting unit more uniform.

However, since there are limitations such as the unit size that may be adjusted in the actual manufacturing process, it may be difficult to manufacture all laser emitting units with different sizes.

Therefore, a laser emitting array designed as described below through FIG. 25 may be required.

Referring to FIG. 25, a laser emitting array 5700 according to an embodiment may include a plurality of laser emitting units, at least one sub-array, and at least one power supply.

Herein, the at least one sub-array may refer to a group of laser emitting units that are operatively connected among the plurality of laser emitting units, refer to a group of laser emitting units that are physically connected, refer to a group of laser emitting units that are connected to the same power supply, refer to a group of laser emitting units defined by the at least one upper conductor, and refer to a group of laser emitting units defined by a capacitor that is electrically connected to the at least one power supply, but is not limited thereto.

Referring again to FIG. 25, the laser emitting array 5700 according to an embodiment may include at least one sub-array.

For example, the laser emitting array 5700 according to an embodiment may include a first sub-array 5710, but is not limited thereto.

In addition, the laser emitting array 5700 according to an embodiment may include at least one power supply unit.

For example, the laser emitting array 5700 according to an embodiment may include a first power supply unit 5730 for supplying energy to the first sub-array 5710, but is not limited thereto.

In addition, the laser emitting array 5700 according to an embodiment may include a plurality of laser emitting units.

For example, the laser emitting array 5700 according to an embodiment may include the first sub-array 5710, and the first sub-array 5710 may include a first laser emitting unit 5711, a second laser emitting unit 5712, and a third laser emitting unit 5713, but is not limited thereto.

However, since the above-described contents may be applied to the laser emitting array 5700, the first sub-array 5710, the first laser emitting unit 5711, the second laser emitting unit 5712, the third laser emitting unit 5713, and the first power supply unit 5730 according to an embodiment, redundant descriptions will be omitted.

Referring again to FIG. 25, the laser emitting array 5700 according to an embodiment may be designed so that the longer the length of the electrical path from the power supply to the laser emitting unit, the larger the size of the laser emitting unit.

For example, according to an embodiment, the first laser emitting unit 5711 included in the first sub-array 5710 may be arranged so that the length of the electrical path from the first power supply unit 5730 is longer than that of the second laser emitting unit 5712 included in the first sub-array 5710, and the second laser emitting unit 5712 may be arranged so that the length of the electrical path from the first power supply unit 5730 is longer than that of the third laser emitting unit 5713, in which the size of the first laser emitting unit 5711 may be designed to be larger than that of the second laser emitting unit 5712, and the size of the second laser emitting unit 5712 may be designed to be larger than that of the third laser emitting unit 5713, but is not limited thereto.

In addition, the laser emitting array 5700 according to an embodiment may include a laser emitting unit set including a plurality of laser emitting units provided in the same size.

For example, the laser emitting array 5700 according to an embodiment may include, but is not limited to, a first laser emitting unit set 5721 provided in a first size, a second laser emitting unit set 5722 provided in a second size, and a third laser emitting unit set 5723 provided in a third size.

In addition, the laser emitting array 5700 according to an embodiment may be designed such that the longer the length of the electrical path from the power supply unit to the laser emitting unit set, the larger the size of the laser emitting unit included in the laser emitting unit set.

For example, according to an embodiment, the first laser emitting unit set 5721 may be arranged so that the length of the electrical path from the first power supply 5730 is longer than that of the second laser emitting unit set 5722, and the second laser emitting unit set 5722 may be arranged so that the length of the electrical path from the first power supply 5730 is longer than that of the third laser emitting unit set 5723, in which the first size may be larger than the second size, and the second size may be designed to be larger than the third size, but is not limited thereto.

The design for improving the uniformity of the power of the laser emitted from the laser emitting array by adjusting the size of the laser emitting units has been described referring to FIGS. 16 to 25.

However, when the size of the laser emitting unit having the smallest size among the laser emitting units is reduced to improve the uniformity of the laser power emitted from the laser emitting array, in as state that the size of the laser emitting unit having the largest size among the laser emitting units included in the laser emitting array is fixed, the overall resistance may increase, thereby reducing the overall intensity of the laser power emitted from the laser emitting array.

In addition, when an amount of increase in the laser power emitted from the laser emitting unit having the largest size among the laser emitting units is smaller compared to an amount of decrease in the laser power emitted from the laser emitting unit having the smallest size among the laser emitting units, the overall efficiency of the lasers emitted from the laser emitting array may decrease.

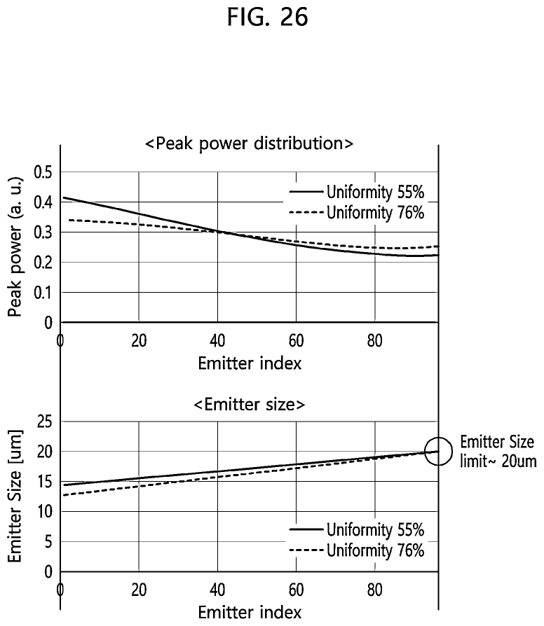

This will be explained more specifically through FIG. 26 as an example.

FIG. 26 is a diagram illustrating the size and power of laser emitting units included in a laser emitting array designed according to an embodiment.

First, in a graph for <Emitter size> of FIG. 26, the X-axis indicates the index of laser emitting units included in the laser emitting array, and the Y-axis indicates the size of each laser emitting unit.

In addition, in a graph for <Peak Power distribution> of FIG. 26, the X-axis indicates the index of laser emitting units included in the laser emitting array, and the Y-axis indicates an axis for the power of the laser emitted from each laser emitting unit.

Herein, the index of the laser emitting units may be numbered in ascending order starting from the shortest electrical path from the power supply to each laser emitting unit.

In addition, FIG. 26 illustrates the graphs for a laser emitting array designed according to two examples.

Herein, the laser emitting array according to the first embodiment may be configured to design the size of the laser emitting unit in such a manner that the maximum size of the laser emitting unit is 20 μm and the power of the laser emitted with the smallest power is 55% of the power of the laser emitted with the largest power, among the lasers emitted from the laser emitting array.

In addition, the laser emitting array according to the second embodiment is configured to design the size of the laser emitting units such that the maximum size of the laser emitting unit size of 20 μm and the power of the laser emitted with the smallest power is 76% of the power of the laser emitted with the largest power, among the lasers emitted from the laser emitting array.

In addition, referring to FIG. 26, the index of the laser emitting unit that emits the laser with the smallest power among the lasers emitted from the laser emitting array may be 100, and the index of the laser emitting unit that emits the laser with the largest power among the lasers emitted from the laser emitting array may be 1, but is not limited thereto.

In addition, referring to FIG. 26, the power of the laser emitted with the smallest power may be 0.23, and the power of the laser emitted with the largest power may be 0.42, among the lasers emitted from the laser emitting array designed according to the first embodiment.

In addition, referring to FIG. 26, the power of the laser emitted with the smallest power may be 0.25, and the power of the laser emitted with the largest power may be 0.33, among the lasers emitted from the laser emitting array designed according to the second embodiment.

Therefore, referring to FIG. 26, when the design is changed from the laser emitting array according to the first embodiment in which the uniformity of the lasers emitted from the laser emitting array is designed to be 55%, to the laser emitting array according to the second embodiment in which the uniformity of the lasers emitted from the laser emitting array is designed to be 76%, the power of the laser emitted with the largest power decreases by 20% from 0.42 to 0.33, while the power of the laser emitted with the smallest power increases by 9% from 0.23 to 0.25.

That is, referring to FIG. 26, when the design is changed from a laser emitting array designed according to the first embodiment to a laser emitting array designed according to the second embodiment, the uniformity of lasers emitted from the laser emitting array may increase, but the power of the laser emitted with the highest power may decrease significantly, and the power of the laser emitted with the lowest power may increase slightly, whereby the overall efficiency of the lasers emitted from the laser emitting array may decrease.

Therefore, when securing the uniformity of the lasers emitted from the laser emitting array to a certain level, an additional design approach may be required to secure the uniformity of the amount of light received by each detecting unit included in the laser detecting array included in the LiDAR device.

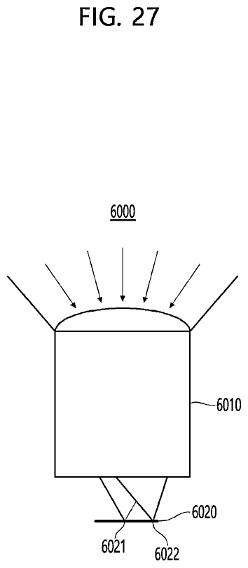

FIG. 27 is a diagram illustrating the illumination of the receiving optics included in the LiDAR device according to an embodiment.

Referring to FIG. 27, the LiDAR device 6000 according to an embodiment may include a receiving optic 6010 and a laser detecting array 6020, and the laser detecting array 6020 may include a first laser detecting unit 6021 and a second laser detecting unit 6022.

Herein, since the above-described contents may be applied to the receiving optic 6010, the laser detecting array 6020, the first laser detecting unit 6021, and the second laser detecting unit 6022, redundant descriptions will be omitted.

According to an embodiment, light incident on the receiving optic 6010 at a specific angle may reach a specific area on the image plane of the receiving optic 6010.

Herein, an amount of light reaching a specific area on the image plane through the receiving optic 6010 may be defined as the illuminance on a specific area.

For example, the amount of light reaching a first region of the image plane of the receiving optic 6010 through the receiving optic 6010 may be defined as the illuminance for the first region on the image plane, and the amount of light reaching a second region of the image plane of the receiving optic 6010 through the receiving optic 6010 may be defined as the illuminance for the second region on the image plane, but is not limited thereto.

In addition, according to an embodiment, light incident on the receiving optic 6010 at a specific angle may reach a specific region on the focal plane of the receiving optic 6010.

Herein, the amount of light reaching a specific region on the focal plane through the receiving optic 6010 may be defined as the illuminance for a specific region.

For example, the amount of light reaching a first region on the focal plane of the receiving optic 6010 through the receiving optic 6010 may be defined as the illumination for the first region on the focal plane, and the amount of light reaching a second region on the focal plane of the receiving optic 6010 through the receiving optic 6010 may be defined as the illumination for the second region on the focal plane, but the disclosure is not limited thereto.

In addition, according to an embodiment, light incident on the receiving optic 6010 at a specific angle may reach a specific region on the laser detecting array 6020.

Herein, the amount of light reaching a specific region on the laser detecting array 6020 through the receiving optic 6010 may be defined as the illumination for a specific region.

For example, the amount of light reaching a first region on the laser detecting array 6020 through the receiving optic 6010 may be defined as the illuminance for the first region on the laser detecting array 6020, and the amount of light reaching a second region on the laser detecting array 6020 through the receiving optic 6010 may be defined as the illuminance for the second region on the laser detecting array 6020, but is not limited thereto.

In addition, according to an embodiment, light incident on the receiving optic 6010 at a specific angle may reach a specific detecting unit on the laser detecting array 6020.

Herein, the amount of light reaching a specific detecting unit on the laser detecting array 6020 through the receiving optic 6010 may be defined as the illuminance on a specific detecting unit.

For example, the amount of light reaching a first detecting unit 6021 on the laser detecting array 6020 through the receiving optic 6010 may be defined as the illuminance for the first detecting unit 6021 on the laser detecting array 6020, and the amount of light reaching a second detecting unit 6022 on the laser detecting array 6020 through the receiving optic 6010 may be defined as the illuminance for the second detecting unit 6022 on the laser detecting array 6020, but the disclosure is not limited thereto.

In addition, as described above, since the amounts of light reaching specific areas, specific detecting units, and the like may be different in absolute size depending on the amount of light incident on the receiving optic 6010, the illuminances for the specific areas, the specific detecting units, and the like are preferably compared with each other, as a relative illuminance for the light incident on the receiving optic 6010 with the same amount of light.

For example, the illuminance for a first area on the image plane of the receiving optic 6010 and the illuminance for a second area on the image plane of the receiving optic 6010 may be compared with each other, in which the illuminance for the first area on the image plane of the receiving optic 6010 may be the amount of light which is measured in the first area on the image plane based on light incident on the receiving optic 6010 at the first light amount and the first angle, and the illuminance for the second area on the image plane of the receiving optic 6010 may be the amount of light which is measured in the second area on the image plane based on light incident on the receiving optic 6010 at the first light amount and the second angle.

In addition, for example, the illuminance for a first area on the focal plane of the receiving optic 6010 and the illuminance for a second area on the focal plane of the receiving optic 6010 may be compared with each other, in which the illuminance for the first area on the focal plane of the receiving optic 6010 may be a light amount which is measured in the first area on the focal plane based on light incident on the receiving optic 6010 at a first light amount and a first angle, and the illuminance for the second area on the focal plane of the receiving optic 6010 may be a light amount which is measured in the second area on the focal plane based on light incident on the receiving optic 6010 at a first light amount and a second angle.

In addition, for example, the illuminance for the first area on the laser detecting array 6020 and the illuminance for the second area on the laser detecting array 6020 may be compared with each other, in which the illuminance for the first area on the laser detecting array 6020 may be the amount of light which is measured in the first area on the laser detecting array 6020 based on light incident on the receiving optic 6010 at the first light amount and the first angle, and the illuminance for the second area on the laser detecting array 6020 may be the amount of light which is measured in the second area on the laser detecting array 6020 based on light incident on the receiving optic 6010 at the first light amount and the second angle.

In addition, for example, the illuminance of the first detecting unit 6021 on the laser detecting array 6020 and the illuminance of the second detecting unit 6022 on the laser detecting array 6020 may be compared with each other, in which the illuminance of the first detecting unit 6021 on the laser detecting array 6020 may be the light amount which is measured by the first detecting unit 6021 on the laser detecting array 6020 based on the light incident on the receiving optic 6010 at the first light amount and the first angle, and the illuminance of the second detecting unit 6022 on the laser detecting array 6020 may be the light amount which is measured by the second detecting unit 6022 on the laser detecting array 6020 based on the light incident on the receiving optic 6010 at the first light amount and the second angle.

In addition, as described above, the illumination for a specific area, a specific detecting unit, and the like may be referred to as relative illumination.

Herein, the relative illumination may usually be obtained by comparing with the area with the greatest illumination among specific areas.

For example, the relative illuminance for the first region on the image plane of the receiving optic 6010 may refer to a ratio of the illuminance to the third region with the greatest illuminance among the regions on the image plane of the receiving optic 6010, and the relative illuminance for the second region on the image plane of the receiving optic 6010 may refer to a ratio of the illuminance to the third region with the greatest illuminance among the regions on the image plane of the receiving optic 6010, but the disclosure is not limited thereto.

In addition, for example, the relative illuminance for the first region on the focal plane of the receiving optic 6010 may refer to a ratio of the illuminance to the third region with the greatest illuminance among the regions on the focal plane of the receiving optic 6010, and the relative illuminance for the second region on the focal plane of the receiving optic 6010 may refer to a ratio of the illuminance to the third region with the greatest illuminance among the regions on the focal plane of the receiving optic 6010, but the disclosure is not limited thereto.

In addition, for example, the relative illuminance for the first region on the laser detecting array 6020 may refer to a ratio of the illuminance to the third region with the greatest illuminance among the regions on the laser detecting array 6020, and the relative illuminance for the second region on the laser detecting array 6020 may refer to a ratio of the illuminance to the third region with the greatest illuminance among the regions on the laser detecting array 6020, but the disclosure is not limited thereto.

In addition, for example, the relative illuminance for the first detecting unit 6021 on the laser detecting array 6020 may refer to a ratio of the illuminance to the third detecting unit having the largest illuminance among the detecting units on the laser detecting array 6020, and the relative illuminance for the second detecting unit 6022 on the laser detecting array 6020 may refer to a ratio of the illuminance to the third detecting unit having the largest illuminance among the detecting units on the laser detecting array 6020, but the disclosure is not limited thereto.

The illuminance and relative illuminance of the receiving optic 6010 according to an embodiment have been described above.

Therefore, the design of the illuminance or relative illuminance of the receiving optic 6010 according to an embodiment makes it possible to secure the uniformity of the amount of light received by each detecting unit included in the laser detecting array 6020 according to an embodiment, which will be described in more detail hereinafter.

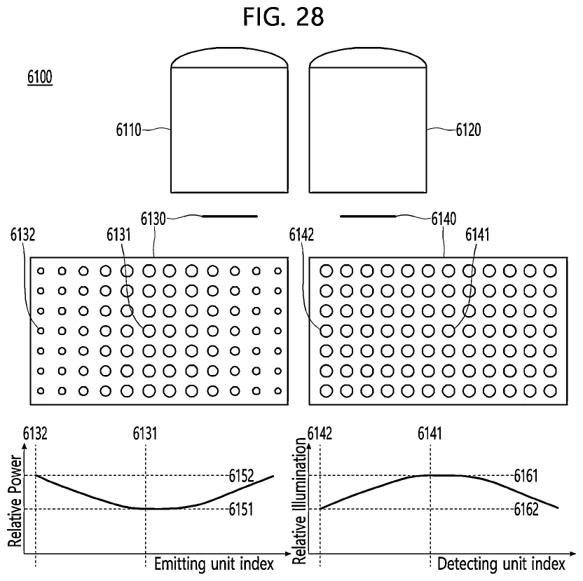

FIG. 28 is a diagram illustrating a LIDAR device according to an embodiment.

Referring to FIG. 28, the LiDAR device 6100 according to an embodiment may include a transmission module and a reception module.

Herein, the transmission module may include a transmission optic 6110 and a laser emitting array 6130, and the reception module may include a reception optic 6120 and a laser detecting array 6140.

In addition, since the above-described contents may be applied to the transmission module, the reception module, the transmission optic 6110, the reception optic 6120, the laser emitting array 6130, and the laser detecting array 6140, redundant descriptions will be omitted.

According to an embodiment, the laser emitted from the laser emitting array 6130 may be steered in various directions by the transmission optics 6110.

For example, the first laser emitted from the first laser emitting unit 6131 included in the laser emitting array 6130 may be steered by the transmission optic 6110 to be emitted in a first direction, and the second laser emitted from the second laser emitting unit 6132 included in the laser emitting array 6130 may be steered by the transmission optic 6110 to be emitted in a second direction, but is not limited thereto.

In addition, according to an embodiment, light incident on the receiving optic 6120 from various directions may be distributed to different detecting units by the receiving optic 6120.

For example, light incident on the receiving optic 6120 from a first direction may be distributed into a first detecting unit 6141 by the receiving optic 6120, and light incident on the receiving optic 6120 from a second direction may be distributed into a second detecting unit 6142 by the receiving optic 6120, but is not limited thereto.

In addition, according to an embodiment, when a laser emitted from the laser emitting array 6130 is reflected from a target, it may be detected by the laser detecting array 6140.

For example, the first laser emitted from the first laser emitting unit 6131 included in the laser emitting array 6130 may be steered by the transmission optic 6110 to be emitted in the first direction, and when the first laser is reflected from the target, it may be incident on the reception optic 6120 and then distributed into the first detecting unit 6141 by the reception optic 6120; and the second laser emitted from the second laser emitting unit 6132 included in the laser emitting array 6130 may be steered by the transmission optic 6110 to be emitted in the second direction, and when the second laser is reflected from the target, it may be incident on the reception optic 6120 and distributed to the second detecting unit 6142 by the reception optic 6120, but the disclosure is not limited thereto.

Herein, the first laser emitting unit 6131 and the first detecting unit 6141 may be optically coupled to each other, and the second laser emitting unit 6132 and the second detecting unit 6142 may be optically coupled to each other.

In addition, according to an embodiment, since the contents described in FIG. 23 and FIG. 24 may be applied to the laser emitting array 6130, redundant descriptions will be omitted.

In addition, according to an embodiment, the first laser emitting sub-array including the first laser emitting unit 6131 and the second laser emitting unit 6132 may be included.

Herein, the laser emitting sub-array may refer to a group of laser emitting units that are operatively connected among a plurality of laser emitting units, may refer to a group of laser emitting units that are physically connected, may refer to a group of laser emitting units that are connected to the same power supply, may refer to a group of laser emitting units defined by at least one upper conductor, and may refer to a group of laser emitting units defined by a capacitor that is electrically connected to the power supply, but is not limited thereto.

In addition, according to an embodiment, the plurality of laser emitting units included in the laser emitting sub-array may have more increased size as they are disposed closer to the center of the laser emitting array.

For example, according to an embodiment, the first laser emitting unit 6131 included in the first laser emitting sub-array may be disposed closer to the center of the laser emitting array 6130 than the second laser emitting unit 6132 included in the first laser emitting sub-array, and the size of the first laser emitting unit 6131 may be provided to be larger than the size of the second laser emitting unit 6132.

In addition, according to an embodiment, the illumination for a specific area of the receiving optic 6120 may be designed to be associated with the sizes of the laser emitting units included in the laser emitting array 6130.

For example, according to an embodiment, in a state that the first detecting unit 6141 optically coupled with the first laser emitting unit 6131 is arranged in a first region on the image plane of the receiving optic 6120, and the second detecting unit 6142 optically coupled with the second laser emitting unit 6132 is arranged in a second region on the image plane of the receiving optic 6120, when the size of the first laser emitting unit 6131 is provided to be larger than the size of the second laser emitting unit 6132, the illumination for the first region on the image plane of the receiving optic 6120 may be designed to be greater than the illumination for the second region on the image plane of the receiving optic 6120, but is not limited thereto.

In addition, for example, according to an embodiment, in a state that the first detecting unit 6141 optically coupled with the first laser emitting unit 6131 is arranged in a first region on the focal plane of the receiving optic 6120, and a second detecting unit 6142 optically coupled with the second laser emitting unit 6132 is arranged in a second region on the focal plane of the receiving optic 6120, when the size of the first laser emitting unit 6131 is provided to be larger than the size of the second laser emitting unit 6132, the illuminance for the first region on the focal plane of the receiving optic 6120 may be designed to be greater than the illuminance for the second region on the focal plane of the receiving optic 6120, but is not limited thereto.

In addition, for example, according to an embodiment, in a state that the first detecting unit 6141 optically coupled with the first laser emitting unit 6131 is arranged in the first region on the laser detecting array 6140, and a second detecting unit 6142 optically coupled with the second laser emitting unit 6132 is arranged in a second region on the laser detecting array 6140, when the size of the first laser emitting unit 6131 is provided to be larger than the size of the second laser emitting unit 6132, the illuminance of the receiving optic 6120 for the first region on the laser detecting array 6140 may be designed to be greater than that of the receiving optic 6120 for the second region on the laser detecting array 6140, but is not limited thereto.

In addition, for example, in a state that the first detecting unit 6141 is optically coupled with the first laser emitting unit 6131 and the second detecting unit 6142 is optically coupled with the second laser emitting unit 6132, when the size of the first laser emitting unit 6131 is provided to be larger than the size of the second laser emitting unit 6132, the illuminance of the receiving optic 6120 to the first detecting unit 6141 may be designed to be larger than that of the receiving optic 6120 to the second detecting unit 6142, but the disclosure is not limited thereto.

In addition, according to an embodiment, the relative illuminance for a specific area of the receiving optic 6120 may be designed to be associated with the size of the laser emitting units included in the laser emitting array 6130.

For example, according to an embodiment, in a state that the first detecting unit 6141 optically coupled with the first laser emitting unit 6131 is arranged in a first region on the image plane of the receiving optic 6120, and the second detecting unit 6142 optically coupled with the second laser emitting unit 6132 is arranged in a second region on the image plane of the receiving optic 6120, when the size of the first laser emitting unit 6131 is provided to be larger than that of the second laser emitting unit 6132, the relative illumination of the first region on the image plane of the receiving optic 6120 may be designed to be larger than the relative illumination of the second region on the image plane of the receiving optic 6120, but the disclosure is not limited thereto.

In addition, for example, according to an embodiment, in a state that the first detecting unit 6141 optically coupled with the first laser emitting unit 6131 is arranged in the first region on the focal plane of the receiving optic 6120, and the second detecting unit 6142 optically coupled with the second laser emitting unit 6132 is arranged in the second region on the focal plane of the receiving optic 6120, when the size of the first laser emitting unit 6131 is provided to be larger than the size of the second laser emitting unit 6132, the relative illuminance for the first region on the focal plane of the receiving optic 6120 may be designed to be larger than that for the second region on the focal plane of the receiving optic 6120, but is not limited thereto.

In addition, for example, according to an embodiment, in a state that the first detecting unit 6141 optically coupled with the first laser emitting unit 6131 is arranged in the first region on the laser detecting array 6140, and the second detecting unit 6142 optically coupled with the second laser emitting unit 6132 is arranged in the second region on the laser detecting array 6140, when the size of the first laser emitting unit 6131 is provided to be larger than that of the second laser emitting unit 6132, the relative illuminance of the receiving optic 6120 for the first region on the laser detecting array 6140 may be designed to be larger than that of the receiving optic 6120 for the second region on the laser detecting array 6140, but is not limited thereto.

In addition, for example, in a state that the first detecting unit 6141 is optically coupled with the first laser emitting unit 6131 and the second detecting unit 6142 is optically coupled with the second laser emitting unit 6132, when the size of the first laser emitting unit 6131 is provided to be larger than that of the second laser emitting unit 6132, the relative illuminance 6161 of the receiving optic 6120 with respect to the first detecting unit 6141 may be designed to be larger than the relative illuminance 6162 of the receiving optic 6120 with respect to the second detecting unit 6142, but is not limited thereto.

Additionally, according to an embodiment, in a state that the illumination for a specific area of the receiving optic 6120 may be designed to be associated with the resistance of the laser emitting units included in the laser emitting array 6130.

For example, according to an embodiment, in a state that the first detecting unit 6141 optically coupled with the first laser emitting unit 6131 is disposed in the first region on the image plane of the receiving optic 6120, and the second detecting unit 6142 optically coupled with the second laser emitting unit 6132 is disposed in the second region on the image plane of the receiving optic 6120, when the resistance of the first laser emitting unit 6131 is provided to be smaller than the resistance of the second laser emitting unit 6132, the illumination for the first region on the image plane of the receiving optic 6120 may be designed to be greater than that for the second region on the image plane of the receiving optic 6120, but is not limited thereto.

In addition, for example, according to an embodiment, in a state that the first detecting unit 6141 optically coupled with the first laser emitting unit 6131 is arranged in the first region on the focal plane of the receiving optic 6120, and the second detecting unit 6142 optically coupled with the second laser emitting unit 6132 is arranged in the second region on the focal plane of the receiving optic 6120, when the resistance of the first laser emitting unit 6131 is provided to be smaller than that of the second laser emitting unit 6132, the illumination for the first region on the focal plane of the receiving optic 6120 may be designed to be greater than that for the second region on the focal plane of the receiving optic 6120, but is not limited thereto.

In addition, for example, according to an embodiment, in a state that the first detecting unit 6141 optically coupled with the first laser emitting unit 6131 is arranged in the first region on the laser detecting array 6140, and the second detecting unit 6142 optically coupled with the second laser emitting unit 6132 is arranged in the second region on the laser detecting array 6140, when the resistance of the first laser emitting unit 6131 is provided to be smaller than that of the second laser emitting unit 6132, the illuminance of the receiving optic 6120 for the first region on the laser detecting array 6140 may be designed to be greater than that of the receiving optic 6120 for the second region on the laser detecting array 6140, but is not limited thereto.

In addition, for example, in a state that the first detecting unit 6141 is optically coupled with the first laser emitting unit 6131 and the second detecting unit 6142 is optically coupled with the second laser emitting unit 6132, when the resistance of the first laser emitting unit 6131 is provided to be smaller than that of the second laser emitting unit 6132, the illumination of the receiving optic 6120 for the first detecting unit 6141 may be designed to be greater than that of the receiving optic 6120 for the second detecting unit 6142, but is not limited thereto.

In addition, according to an embodiment, the relative illuminance for a specific area of the receiving optic 6120 may be designed to be associated with the resistance of the laser emitting units included in the laser emitting array 6130.

For example, according to an embodiment, in a state that a first detecting unit 6141 optically coupled with the first laser emitting unit 6131 is disposed in a first region on the image plane of the receiving optic 6120, and a second detecting unit 6142 optically coupled with the second laser emitting unit 6132 is disposed in a second region on the image plane of the receiving optic 6120, when the resistance of the first laser emitting unit 6131 is provided to be smaller than that of the second laser emitting unit 6132, the relative illumination of the first region on the image plane of the receiving optic 6120 may be designed to be greater than that of the second region on the image plane of the receiving optic 6120, but is not limited thereto.

In addition, for example, according to an embodiment, in a state that the first detecting unit 6141 optically coupled with the first laser emitting unit 6131 is arranged in the first region on the focal plane of the receiving optic 6120, and the second detecting unit 6142 optically coupled with the second laser emitting unit 6132 is arranged in the second region on the focal plane of the receiving optic 6120, when the resistance of the first laser emitting unit 6131 is provided to be smaller than that of the second laser emitting unit 6132, the relative illuminance of the first region on the focal plane of the receiving optic 6120 may be designed to be greater than that of the second region on the focal plane of the receiving optic 6120, but is not limited thereto.

In addition, for example, according to an embodiment, in a state that the first detecting unit 6141 optically coupled with the first laser emitting unit 6131 is arranged in the first region on the laser detecting array 6140, and the second detecting unit 6142 optically coupled with the second laser emitting unit 6132 is arranged in the second region on the laser detecting array 6140, when the resistance of the first laser emitting unit 6131 is provided to be smaller than that of the second laser emitting unit 6132, the relative illuminance of the receiving optic 6120 for the first region on the laser detecting array 6140 may be designed to be greater than that of the receiving optic 6120 for the second region on the laser detecting array 6140, but is not limited thereto.

In addition, for example, in a state that the first detecting unit 6141 is optically coupled with the first laser emitting unit 6131 and the second detecting unit 6142 is optically coupled with the second laser emitting unit 6132, when the resistance of the first laser emitting unit 6131 is provided to be smaller than that of the second laser emitting unit 6132, the relative illuminance 6161 of the receiving optic 6120 for the first detecting unit 6141 may be designed to be greater than the relative illuminance 6162 of the receiving optic 6120 for the second detecting unit 6142, but is not limited thereto.

In addition, according to an embodiment, the power of the lasers emitted from the laser emitting array 6130 may be associated with the length of the electrical path from the power supply, the size of the resistance, the size of the laser emitting unit, and the like, and since the above-described contents may be applied to this, redundant descriptions will be omitted.

In addition, according to an embodiment, the power of the lasers emitted from the laser emitting array 6130 may be different from each other.

For example, when the power 6152 of the laser emitted from the second laser emitting unit 6132 included in the laser emitting array 6130 is 100%, the power 6151 of the laser emitted from the first laser emitting unit 6131 may be less than 100%.

For a more specific example, when the power 6152 of the laser emitted from the second laser emitting unit 6132 included in the laser emitting array 6130 is 100%, the power 6151 of the laser emitted from the first laser emitting unit 6131 may be 55%, but is not limited thereto.

In addition, according to an embodiment, The illumination for a specific area of the receiving optic 6120 may be designed to be associated with the power of the laser emitted from the laser emitting units included in the laser emitting array 6130.

For example, according to an embodiment, in a state that a first detecting unit 6141 optically coupled with the first laser emitting unit 6131 is arranged in a first region on the image plane of the receiving optic 6120, and a second detecting unit 6142 optically coupled with the second laser emitting unit 6132 is arranged in a second region on the image plane of the receiving optic 6120, when the power 6151 of the first laser emitted from the first laser emitting unit 6131 is provided to be smaller than the power 6152 of the second laser emitted from the second laser emitting unit 6132, the illumination for the first region on the image plane of the receiving optic 6120 may be designed to be greater than the illumination for the second region on the image plane of the receiving optic 6120, but is not limited thereto.

Also, for example, according to an embodiment, in a state that the first detecting unit 6141 optically coupled with the first laser emitting unit 6131 is arranged in the first region on the focal plane of the receiving optic 6120, and the second detecting unit 6142 optically coupled with the second laser emitting unit 6132 is arranged in the second region on the focal plane of the receiving optic 6120, when the power 6151 of the first laser emitted from the first laser emitting unit 6131 is provided to be smaller than the power 6152 of the second laser emitted from the second laser emitting unit 6132, the illuminance of the first region on the focal plane of the receiving optic 6120 may be designed to be greater than that of the second region on the focal plane of the receiving optic 6120, but is not limited thereto.

In addition, for example, according to an embodiment, in s state that the first detecting unit 6141 optically coupled with the first laser emitting unit 6131 is arranged in the first region on the laser detecting array 6140, and the second detecting unit 6142 optically coupled with the second laser emitting unit 6132 is arranged in the second region on the laser detecting array 6140, when the power 6151 of the first laser emitted from the first laser emitting unit 6131 is provided to be smaller than the power 6152 of the second laser emitted from the second laser emitting unit 6132, the illuminance of the receiving optic 6120 for the first region on the laser detecting array 6140 of the receiving optic 6120 may be designed to be greater than that of the second region on the laser detecting array 6140 of the receiving optic 6120, but is not limited thereto.

In addition, for example, in a state that the first detecting unit 6141 is optically coupled with the first laser emitting unit 6131 and the second detecting unit 6142 is optically coupled with the second laser emitting unit 6132, when the power 6151 of the first laser emitted from the first laser emitting unit 6131 is provided to be smaller than the power 6152 of the second laser emitted from the second laser emitting unit 6132, the illuminance for the first detecting unit 6141 of the receiving optic 6120 may be designed to be greater than that for the second detecting unit 6142 of the receiving optic 6120, but is not limited thereto.

In addition, according to an embodiment, the relative illuminance for a specific area of the receiving optic 6120 may be designed to be associated with the power of the laser emitted from the laser emitting units included in the laser emitting array 6130.

For example, according to an embodiment, in a state that a first detecting unit 6141 optically coupled with the first laser emitting unit 6131 is arranged in a first region on the image plane of the receiving optic 6120, and a second detecting unit 6142 optically coupled with the second laser emitting unit 6132 is arranged in a second region on the image plane of the receiving optic 6120, when the power 6151 of the first laser emitted from the first laser emitting unit 6131 is provided to be smaller than the power 6152 of the second laser emitted from the second laser emitting unit 6132, the relative illumination of the first region on the image plane of the receiving optic 6120 may be designed to be greater than that of the second region on the image plane of the receiving optic 6120, but is not limited thereto.

In addition, for example, according to an embodiment, in a state that the first detecting unit 6141 optically coupled with the first laser emitting unit 6131 is arranged in the first region on the focal plane of the receiving optic 6120, and the second detecting unit 6142 optically coupled with the second laser emitting unit 6132 is arranged in the second region on the focal plane of the receiving optic 6120, when the power 6151 of the first laser emitted from the first laser emitting unit 6131 is provided to be smaller than the power 6152 of the second laser emitted from the second laser emitting unit 6132, the relative illumination of the first region on the focal plane of the receiving optic 6120 may be designed to be greater than the relative illumination of the second region on the focal plane of the receiving optic 6120, but is not limited thereto.

In addition, for example, according to an embodiment, in a state that the first detecting unit 6141 optically coupled with the first laser emitting unit 6131 is arranged in the first region on the laser detecting array 6140, and the second detecting unit 6142 optically coupled with the second laser emitting unit 6132 is arranged in the second region on the laser detecting array 6140, when the power 6151 of the first laser emitted from the first laser emitting unit 6131 is provided to be smaller than the power 6152 of the second laser emitted from the second laser emitting unit 6132, the relative illuminance for the first region on the laser detecting array 6140 of the receiving optic 6120 may be designed to be greater than the relative illuminance for the second area on the laser detecting array 6140 of the receiving optic 6120, but is not limited thereto.

In addition, for example, in a state that the first detecting unit 6141 is optically coupled with the first laser emitting unit 6131 and the second detecting unit 6142 is optically coupled with the second laser emitting unit 6132, when the power 6151 of the first laser emitted from the first laser emitting unit 6131 is provided to be smaller than the power 6152 of the second laser emitted from the second laser emitting unit 6132, the relative illuminance 6161 of the receiving optic 6120 with respect to the first detecting unit 6141 may be designed to be greater than the relative illuminance 6162 of the receiving optic 6120 with respect to the second detecting unit 6142, but is not limited thereto.

In addition, according to an embodiment, the illumination for a specific area of the receiving optics 6120 may be designed by considering the power of the laser emitted from the laser emitting units included in the laser emitting array 6130.

For example, according to an embodiment, in a state that a first detecting unit 6141 is disposed to be optically coupled with the first laser emitting unit 6131 in a first region on the image plane of the receiving optic 6120, and a second detecting unit 6142 is disposed to be optically coupled with the second laser emitting unit 6132 in a second region on the image plane of the receiving optic 6120, when the power 6151 of the first laser emitted from the first laser emitting unit 6131 is provided as 55% of the power 6152 of the second laser emitted from the second laser emitting unit 6132, the illumination for the second region on the image plane of the receiving optic 6120 may be designed to be 55% of the illumination for the first region on the image plane of the receiving optic 6120, but is not limited to this, and may be designed to be in the range of 40 to 70%.

In addition, for example, according to an embodiment, in a state that the first detecting unit 6141 is arranged to be optically coupled with the first laser emitting unit 6131 in the first region on the focal plane of the receiving optic 6120, and the second detecting unit 6142 is arranged to be optically coupled with the second laser emitting unit 6132 in the second region on the focal plane of the receiving optic 6120, when the power 6151 of the first laser emitted from the first laser emitting unit 6131 is provided as 55% of the power 6152 of the second laser emitted from the second laser emitting unit 6132, the illumination for the second region on the focal plane of the receiving optic 6120 may be designed to be 55% of the illumination for the first region on the focal plane of the receiving optic 6120, but is not limited to this, and may be designed to be in the range of 40-70%.

In addition, for example, according to an embodiment, in a state that a first detecting unit 6141 is arranged to be optically coupled with the first laser emitting unit 6131 in a first region on the laser detecting array 6140, and a second detecting unit 6142 is arranged to be optically coupled with the second laser emitting unit 6132 in a second region on the laser detecting array 6140, when the power 6151 of the first laser emitted from the first laser emitting unit 6131 is provided at 55% of the power 6152 of the second laser emitted from the second laser emitting unit 6132, the illumination of the second region on the laser detecting array 6140 of the receiving optic 6120 may be designed to be 55% of the illuminance for the first region on the laser detecting array 6140 of the receiving optic 6120, but is not limited thereto, and may be designed to be in the range of 40 to 70%.

In addition, for example, in a state that the first detecting unit 6141 is optically coupled with the first laser emitting unit 6131, and the second detecting unit 6142 is optically coupled with the second laser emitting unit 6132, when the power 6151 of the first laser emitted from the first laser emitting unit 6131 is provided as 55% of the power 6152 of the second laser emitted from the second laser emitting unit 6132, the illumination for the second detecting unit 6142 of the receiving optic 6120 may be designed to be 55% of the illumination for the first detecting unit 6141 of the receiving optic 6120, but is not limited thereto, and may be designed to be in the range of 40 to 70%.

In addition, according to an embodiment, the relative illuminance for a specific area of the receiving optics 6120 may be designed by considering the power of the laser emitted from the laser emitting units included in the laser emitting array 6130.

For example, according to an embodiment, in a state that the first detecting unit 6141 is arranged to be optically coupled with the first laser emitting unit 6131 in the first region on the image plane of the receiving optic 6120, and the second detecting unit 6142 is arranged to optically coupled with the second laser emitting unit 6132 in a second region on the image plane of the receiving optic 6120, when the power 6151 of the first laser emitted from the first laser emitting unit 6131 is provided at 55% of the power 6152 of the second laser emitted from the second laser emitting unit 6132, the relative illumination for the second region on the image plane of the receiving optic 6120 may be designed to be 55% of the relative illumination for the first region on the image plane of the receiving optic 6120, but is not limited to this, and may be designed to be in the range of 40 to 70%.

In addition, for example, according to an embodiment, in a state that a first detecting unit 6141 optically coupled with the first laser emitting unit 6131 is arranged in a first region on the focal plane of the receiving optic 6120, and a second detecting unit 6142 optically coupled with the second laser emitting unit 6132 is arranged in a second region on the focal plane of the receiving optic 6120, when the power 6151 of the first laser emitted from the first laser emitting unit 6131 is provided as 55% of the power 6152 of the second laser emitted from the second laser emitting unit 6132, the relative illuminance for the second region on the focal plane of the receiving optic 6120 may be designed to be 55% the relative illuminance for the first region on the focal plane of the receiving optic 6120, but is not limited thereto, and may be designed to be in the range of 40 to 70%.

In addition, for example, according to an embodiment, in a state that a first detecting unit 6141 optically coupled with the first laser emitting unit 6131 is arranged in a first region on the laser detecting array 6140, and a second detecting unit 6142 optically coupled with the second laser emitting unit 6132 is arranged in a second region on the laser detecting array 6140, when the power 6151 of the first laser emitted from the first laser emitting unit 6131 is provided as 55% of the power 6152 of the second laser emitted from the second laser emitting unit 6132, the relative illuminance for the receiving optic 6120 to the second region on the laser detecting array 6140 may be designed to be 55% of the relative illuminance for the first area on the laser detecting array 6140, but is not limited thereto and may be designed to be in the range of 40 to 70%.

In addition, for example, in a state that the first detecting unit 6141 is optically coupled with the first laser emitting unit 6131 and the second detecting unit 6142 is optically coupled with the second laser emitting unit 6132, when the power 6151 of the first laser emitted from the first laser emitting unit 6131 is provided as 55% of the power 6152 of the second laser emitted from the second laser emitting unit 6132, the relative illuminance 6162 of the receiving optic 6120 to the second detecting unit 6142 may be designed to be 55% of the relative illuminance 6161 for the first detecting unit 6141 of the receiving option 6120, but is not limited thereto and may be designed to be in the range of 40˜70%.

In addition, according to an embodiment, the powers of the lasers emitted from the laser emitting units included in the laser emitting array 6130 and the relative illuminance for a specific area of the receiving optics 6120 may be designed to satisfy a specific relationship, and for convenience of explanation, the relationship will be explained based on the first laser emitting unit 6131, the second laser emitting unit 6132, the first detecting unit 6141, and the second detecting unit 6142.

### Relationship Equation

Power of laser emitted from first laser emitting unit/Power of laser emitted from second laser emitting unit*0.8≤Relative illuminance on second detection unit of receiving optics/Relative illuminance on first detection unit of receiving optics≤Power of laser emitted from the first laser emitting unit/Power of laser emitted from second laser emitting unit*1.2

Herein, the first detecting unit 6141 and the first laser emitting unit 6131 may be optically coupled to each other, and the second detecting unit 6142 and the second laser emitting unit 6132 may be optically coupled to each other.

The LiDAR device 6100 according to an embodiment has been described above. However, the LiDAR device 6100 described referring to FIG. 28 may be designed based on the laser emitting array described through FIG. 23 and FIG. 24. Therefore, although LiDAR devices may be designed according to different embodiments of the present disclosure by introducing the technical idea described in FIG. 28 based on the laser emitting array described through FIGS. 16 to 25, descriptions on these embodiments would be redundant and thus will be omitted.

The method according to the embodiment may be implemented in the form of program instructions that may be executed through various computer means and recorded on a computer-readable medium. The computer-readable medium may include program instructions, data files, data structures, etc., singly or in combination. Program instructions recorded on the medium may be specially designed and configured for the embodiment or may be known and available to those skilled in the art of computer software. Examples of computer-readable recording media include magnetic media such as hard disks, floppy disks, and magnetic tapes; optical media such as CD-ROM and DVD; magneto-optical media, such as a floptical disk; and hardware devices specifically configured to store and execute program instructions, such as ROM, RAM, flash memory, etc. Examples of program instructions include machine language code, such as that produced by a compiler, as well as high-level language code that may be executed by a computer using an interpreter, etc. The hardware devices described above may be configured to operate as one or more software modules to perform the operations of the embodiments, and vice versa.

As described above, although the embodiments have been described with limited examples and drawings, those skilled in the art will be able to make various modifications and variations from the above description. For example, even though the techniques described may be performed in a different order than the method described, and/or the components of the described system, structure, device, circuit, and the like are combined in a form different from the described method, or are replaced or substituted by other components or equivalents, adequate results may be achieved.

Therefore, other implementations, other embodiments, and equivalents of the claims also fall within the scope of the claims described below.

The forms for carrying out the invention may be those described above in the best form for carrying out the invention and various combinations of those described above in the best form for carrying out the invention.

What is claimed is:

1. A laser emitting array comprising:
a first set of vertical cavity surface emitting lasers (VCSELs) arranged along a first axis, wherein each VCSEL comprises an upper electrode and a lower electrode;
a first upper connection line extended along the first axis between a first end and a second end and configured to be electrically connected to the upper electrodes of the first set of VCSELs;
a first side pad electrically connected to the first end of the first upper connection line via a first wire, wherein the first side pad is electrically connected to a first electric source; and
a second side pad electrically connected to the second end of the first upper connection line via a second wire,
wherein the second side pad is electrically connected to a second electric source,
wherein the first set of VCSELs comprise a first VCSEL and a second VCSEL, the first VCSEL being positioned at an edge of the first upper connection line and the second VCSEL being positioned at a middle section of the first upper connection line, and
wherein a diameter of the second VCSEL is greater than a diameter of the first VCSEL, so as to allow an electric resistance of the second VCSEL to be smaller than an electric resistance of the first VCSEL.

2. The laser emitting array of claim 1, wherein the lower electrode of each VCSEL of the first set of VCSELs is electrically connected to a ground.

3. The laser emitting array of claim 2, wherein a potential of the lower electrode of each VCSEL is configured to be zero in response to each of the first set of VCSELs operating.

4. The laser emitting array of claim 3, wherein a first potential of a first upper electrode of the first VCSEL is configured to be generated by the first electric source and the second electric source in response to the first VCSEL operating,
wherein a second potential of a second upper electrode of the second VCSEL is configured to be generated by the first electric source and the second electric source in response to the second VCSEL operating, and
wherein a difference between the first potential of the first upper electrode and the second potential of the second upper electrode is caused by at least one of:
a difference between a length of a first electric path between the first side pad and the first VCSEL and a length of a second electric path between the first side pad and the second VCSEL, or
a difference between a length of a third electric path between the second side pad and the first VCSEL and a length of a fourth electric path between the second side pad and the second VCSEL.

5. The laser emitting array of claim 4, wherein the difference in resistance between the first VCSEL and the second VCSEL is configured to reduce a difference in current values flowing through the first VCSEL and the second VCSEL, caused by the difference between the first potential of the first upper electrode and the second potential of the second upper electrode.

6. The laser emitting array of claim 1, wherein a diameter of each VCSEL of the first set of VCSELs is configured to gradually increase in response to each VCSEL being positioned closer to the middle section of the first upper connection line.

7. The laser emitting array of claim 1, wherein the first set of VCSELs comprise a third VCSEL being positioned immediately adjacent to the first VCSEL and a fourth VCSEL being positioned immediately adjacent to the second VCSEL, and
wherein the third VCSEL and the fourth VCSEL are positioned between the first VCSEL and the second VCSEL.

8. The laser emitting array of claim 7, wherein a diameter of the third VCSEL is the same as the diameter of the first VCSEL, and
wherein a diameter of the fourth VCSEL is the same as the diameter of the second VCSEL.

9. The laser emitting array of claim 7, wherein a diameter of the third VCSEL is greater than the diameter of the first VCSEL, and
wherein a diameter of the fourth VCSEL is smaller than the diameter of the second VCSEL.

10. A light detection and ranging (LiDAR) device, comprising:
a laser emitting array configured to emit laser;
a transmission optic configured to steer the laser;
a light detecting array configured to detect light; and
a reception optic configured to focus an incident light to the light detecting array,
wherein the laser emitting array comprises:
a first set of vertical cavity surface emitting lasers (VCSELs) arranged along a first axis, wherein each VCSEL comprises an upper electrode and a lower electrode;
a first upper connection line extended along the first axis between a first end and a second end and configured to be electrically connected to the upper electrodes of the first set of VCSELs;
a first side pad electrically connected to the first end of the first upper connection line via a first wire, wherein the first side pad is electrically connected to a first electric source; and
a second side pad electrically connected to the second end of the first upper connection line via a second wire,
wherein the second side pad is electrically connected to a second electric source,
wherein the first set of VCSELs comprise a first VCSEL and a second VCSEL, the first VCSEL being positioned at an edge of the first upper connection line and the second VCSEL being positioned at a middle section of the first upper connection line, and
wherein a diameter of the second VCSEL is greater than a diameter of the first VCSEL, so as to allow an electric resistance of the second VCSEL to be smaller than an electric resistance of the first VCSEL.

11. The LiDAR device of claim 10, wherein the lower electrode of the each VCSEL of the first set of VCSELs is electrically connected to a ground.

12. The LiDAR device of claim 11, wherein a potential of the lower electrode of each VCSEL is configured to be zero in response to each of the set of VCSELs operating.

13. The LiDAR device of claim 12, wherein a first potential of a first upper electrode of the first VCSEL is configured to be generated by the first electric source and the second electric source in response to the first VCSEL operating,
wherein a second potential of a second upper electrode of the second VCSEL is configured to be generated by the first electric source and the second electric source in response to the second VCSEL operating, and
wherein a difference between the first potential of the first upper electrode and the second potential of the second upper electrode is configured to be caused by at least one of:
a difference between a length of a first electric path between the first side pad and the first VCSEL and a length of a second electric path between the first side pad and the second VCSEL, or
a difference between a length of a third electric path between the second side pad and the first VCSEL and a length of a fourth electric path between the second side pad and the second VCSEL.

14. The LiDAR device of claim 13, wherein the difference in resistance between the first VCSEL and the second VCSEL is configured to reduce a difference in current values flowing through the first VCSEL and the second VCSEL, caused by the difference between the first potential of the first upper electrode and the second potential of the second upper electrode.

15. The LiDAR device of claim 14, wherein the difference in current values flowing through the first VCSEL and the second VCSEL is configured to cause a difference between a power of a first laser emitted from the first VCSEL and a power of a second laser emitted from the second VCSEL.

16. The LiDAR device of claim 15, wherein the light detecting array comprises a first set of pixels arranged along the first axis, and
wherein each pixel of the first set of pixels comprises a plurality of single-photon avalanche diodes (SPADs).

17. The LiDAR device of claim 16, wherein the first set of pixels comprise a first pixel and a second pixel, wherein the first pixel is optically coupled with the first VCSEL through the transmission optic and the reception optic, and
wherein the second pixel is optically coupled with the second VCSEL through the transmission optic and the reception optic.

18. The LiDAR device of claim 17, wherein the reception optic is designed so that a first illumination for the first pixel and a second illumination for the second pixel are different from each other.

19. The LiDAR device of claim 18, wherein the first illumination for the first pixel and the second illumination for the second pixel are configured to be determined based on the difference between the power of the first laser and the power of the second laser.

20. The LiDAR device of claim 19, wherein the power of the first laser is greater than the power of the second laser, and
wherein the first illumination for the first pixel is smaller than the second illumination for the second pixel.
